(19) United States
(12) Patent Application Publication
(10) Pub. No.: US 2015/0153646 A1
(43) Pub. Date: Jun. 4, 2015

(54) PHOTOSENSITIVE RESIN COMPOSITION, COLOR FILTER AND METHOD FOR MANUFACTURING THE SAME, AND LIQUID CRYSTAL DISPLAY APPARATUS

(71) Applicant: Chi Mei Corporation, Tainan City (TW)

(72) Inventors: Bar-Yuan Hsieh, Taichung City (TW); Jung-Pin Hsu, Tainan City (TW)

(21) Appl. No.: 14/556,243

(22) Filed: Dec. 1, 2014

(30) Foreign Application Priority Data
Dec. 3, 2013 (TW) 102144213

(51) Int. Cl. G03F 7/075; G02B 5/23; G02B 1/04

(52) U.S. Cl. CPC G03F 7/0758; G02B 1/04; G02B 5/23

(57) ABSTRACT

A photosensitive resin composition is provided. The photosensitive resin composition includes an alkali-soluble resin (A), a polysiloxane polymer (B), a compound (C) containing an ethylenically unsaturated group, a photoinitiator (D), and an organic solvent (E), wherein the alkali-soluble resin (A) includes an alkali-soluble resin (A-1) represented by formula 1.

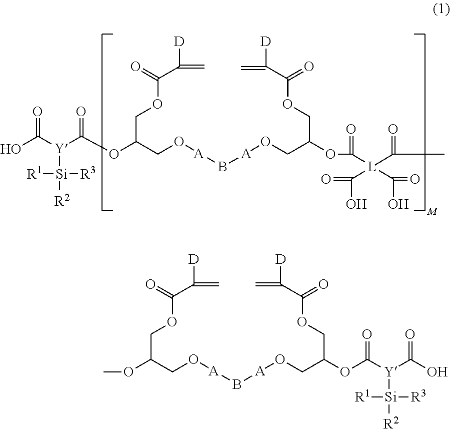

### CROSS-REFERENCE TO RELATED APPLICATION

This application claims the priority benefit of Taiwan application serial no. 102144213, filed on Dec. 3, 2013. The entirety of the above-mentioned patent application is hereby incorporated by reference herein and made a part of this specification.

### BACKGROUND OF THE INVENTION

1. Field of the Invention

The invention is related to a photosensitive resin composition for a color filter of a liquid crystal display apparatus. More particularly, the invention is related to a photosensitive resin composition for a color filter having high precision pattern linearity and small size of foreign matter.

2. Description of Related Art

Due to advantages such as lightweight, thin, and low-power consumption, a liquid crystal display apparatus can be used in various applications such as notebook computers, personal digital assistants, digital cameras, and desktop monitors. However, such type of liquid crystal display apparatus needs to have a color filter with a high color reproduction range.

The color filter is obtained by forming different hues of three colors, red (R), green (G), and blue (B) into stripe or mosaic shapes on a surface of a support such as a glass or a plastic sheet on which a black matrix (BM) is formed.

To date, various methods for manufacturing a color filter have been proposed, wherein the method for manufacturing a color filter using a negative-type photosensitive coloring composition is particularly well known. The negative-type photosensitive coloring composition includes, for instance, a dye, an acrylic resin, a photopolymerization initiator, or an ethylenically unsaturated compound. The negative-type photosensitive coloring composition is cured by the following method: a photopolymerization initiator decomposed or activated by ultraviolet irradiation is initiated due to the formation of a free radical. Then, the ethylenically unsaturated compound activated by the free radical performs free radial polymerization. When using the negative-type photosensitive coloring composition to form a color filter, the negative-type photosensitive coloring composition is generally coated on a substrate and developed after being irradiated by an ultraviolet light via a photomask to obtain a pattern. The pattern formed by the method is heated and calcined such that the pattern is fixedly stuck on the substrate. A pixel pattern is thus formed. The cycle is repeated with the required colors to obtain a pattern of colored coating. However, if the cycle is repeated, a larger segment deviation is generated in the end of the BM and RGB pixels, and uneven color display is generated due to the segment deviation. In order to suppress the segment deviation, a transparent resin layer (protective film) is used for the planarization treatment of the color filter.

In addition, the protective film needs to have features such as the ability to protect the RGB colored layer, heat resistance when liquid crystals are being filled, and hardness against pressure. To achieve the hardness, a photosensitive curable resin composition with high cross linking density is developed (Japanese Patent Laid-Open Publication No. 5-78483). However, the photosensitive curable resin composition is contracted when being cured, thereby generating residual stress. As a result, a defect such as poor high precision pattern linearity readily occurs.

Although Japanese Patent Laid-Open Publication No. H10-133372 discloses that using a protective film composition containing an epoxy compound can improve issues thereof such as poor high precision pattern linearity, the defect of foreign matter having a larger size is still present.

Moreover, in recent years, as personal digital assistants and digital cameras become more compact and lighter, color filters need to be lighter, thinner, and have higher color saturation. Therefore, the concentration of the colorant in the colored composition needs to be increased. Nevertheless, as the high color reproduction range is increased, the concentration of the colorant also needs to be increased, and as a result the amount of resin in the photosensitive colored composition is decreased accordingly. When the resin composition that contributes to the adhesion to the BM is less, the adhesion of the pixels and the BM is decreased, and the pixels readily peel off from the interface with the BM, thereby causing poor high precision pattern linearity.

In general, in the photosensitive resin composition for the applications above, a polyfunctional photocurable monomer having a polymeric unsaturated bond, an alkali-soluble resin and a composition thereof with a photoinitiator are used. For instance, Japanese Patent Laid-Open Publication No. H5-070528 discloses that, in a molecule used, an alkali-soluble photosensitive resin can be manufactured by reacting an epoxy acrylate compound having a fluorene ring with an acid anhydride to improve the issue of poor high precision pattern linearity. However, the defect of oversized foreign matter is still present.

Therefore, how to improve high precision pattern linearity and decrease the size of foreign matter at the same time to meet the requirements of the current industry is a research goal in the technical filed of the invention.

### SUMMARY OF THE INVENTION

Accordingly, the invention provides a photosensitive resin composition for a color filter of a liquid crystal display apparatus. The photosensitive resin composition can improve the issues of poor high precision pattern linearity and large size of foreign matter of the prior photosensitive resin.

The invention provides a photosensitive resin composition. The photosensitive resin composition includes an alkali-soluble resin (A), a polysiloxane polymer (B), a compound (C) containing an ethylenically unsaturated group, a photoinitiator (D), and an organic solvent (E), wherein the alkali-soluble resin (A) includes an alkali-soluble resin (A-1) represented by formula (1),

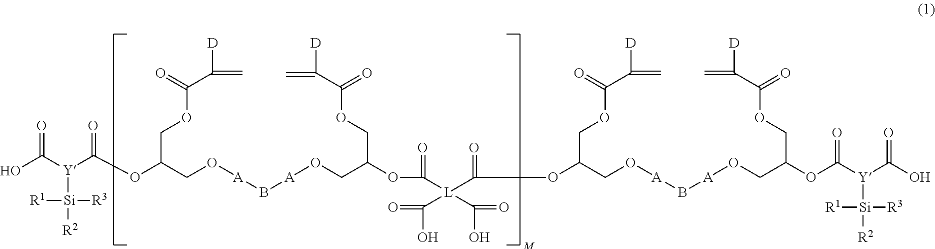

in formula (1), A represents a phenylene group, a hydrogen atom on the phenylene group can be substituted by a C1˜C5 alkyl group, a halogen atom, or a phenyl group; B represents —CO—, —SO₂—, —C(CF₃)₂—, —Si(CH₃)₂—, —CH₂—, —C(CH₃)₂—, —O—, 9,9-fluorenylidene, or a single bond; L represents a tetravalent carboxylic acid residue; Y′ represents a C1˜C20 trivalent organic group; R¹, R², and R³ are each independently a hydrogen atom, a halogen atom, or a monovalent organic group; D represents a hydrogen atom or a methyl group; and M is 1˜20.

In an embodiment of the invention, the alkai-soluble resin (A-1) is obtained by reacting at least a component (a-1), a component (a-2), and a component (a-3), the component (a-1) is a diol compound containing a polymeric unsaturated group, the component (a-2) is a tetracarboxylic acid or an acid dianhydride thereof, and the component (a-3) is a dicarboxylic acid anhydride represented by formula (2),

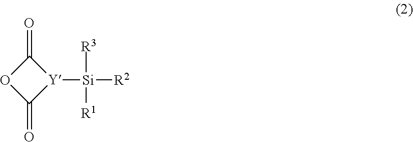

in formula (2), Y′ represents a C1˜C20 trivalent organic group; and R¹, R², and R³ are each independently a hydrogen atom, a halogen atom, or a monovalent organic group.

In an embodiment of the invention, the molar ratio (a-2)/(a-1) of the component (a-1) and the component (a-2) is 0.2˜1.0.

In an embodiment of the invention, the molar ratio (a-3)/(a-1) of the component (a-1) and the component (a-3) is 0.02˜1.6.

In an embodiment of the invention, the alkali-soluble resin (A) further includes an alkali-soluble resin (A-2) other than the alkali-soluble resin (A-1), and the alkali-soluble resin (A-2) is obtained by performing a polymerization reaction on a mixture, wherein the mixture includes an epoxy compound (a-i) having at least two epoxy groups and a compound (a-ii) having at least one carboxylic acid group and at least one ethylenically unsaturated group.

In an embodiment of the invention, the epoxy compound (a-i) having at least two epoxy groups has the structure represented by formula (3) or formula (4):

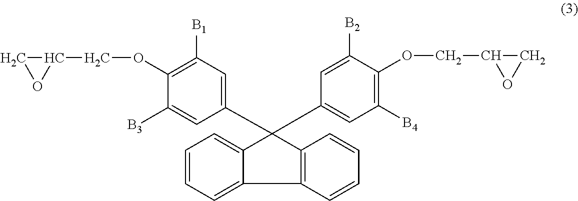

in formula (3), B₁, B₂, B₃, and B₄ are the same or respectively different, and B₁, B₂, B₃, and B₄ respectively represent a hydrogen atom, a halogen atom, a C1˜C5 alkyl group, a C1˜C5 alkoxy group, a C6˜C12 aryl group, or a C6˜C12 aralkyl group;

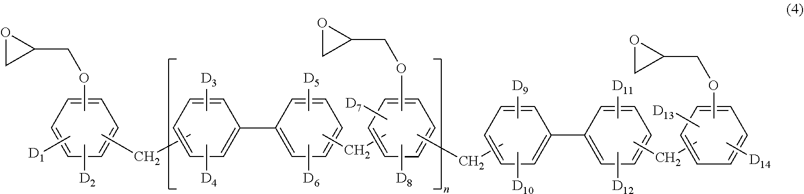

in formula (4), D₁ to D₁₄ are the same or respectively different, D₁ to D₁₄ respectively represent a hydrogen atom, a halogen atom, a C1˜C8 alkyl group, or a C6˜C15 aromatic group, and n represents an integer of 0˜10.

In an embodiment of the invention, the weight ratio of the alkali-soluble resin (A-1) and the alkali-soluble resin (A-2) is between 10/90 and 100/0.

In an embodiment of the invention, the polysiloxane polymer (B) is a copolymer obtained through the hydrolysis and the partial condensation of a silane monomer, wherein the silane monomer includes the compound represented by formula (5):

Si(R¹²)ₜ(OR¹³)₄₋ₜ (5)

wherein t is an integer of 0-3, and when t represents 2 or 3, a plurality of R¹²s are the same or each independently different; R¹² represents a hydrogen atom, a C1˜C10 alkyl group, a C2˜C10 alkenyl group, a C6˜C15 aromatic group, an acid anhydride substituted C1˜C10 alkyl group, an epoxy group substituted C1˜C10 alkyl group, or an epoxy group substituted alkoxy group; R¹³ represents a hydrogen atom, a C1˜C6 alkyl group, a C1˜C6 acyl group, or a C6˜C15 aromatic group, and when 4-t represents 2 or 3, a plurality of R¹³s are the same or each independently different.

In an embodiment of the invention, at least one R¹² represents an acid anhydride group substituted C1˜C10 alkyl group, an epoxy group substituted C1˜C10 alkyl group, or an epoxy group substituted alkoxy group.

In an embodiment of the invention, based on a usage amount of 100 parts by weight of the alkai-soluble resin (A), the usage amount of the polysiloxane polymer (B) is between 10 and 100 parts by weight; the usage amount of the compound (C) containing an ethylenically unsaturated group is between 40 and 400 parts by weight; the usage amount of the photoinitiator (D) is between 10 and 100 parts by weight; and the usage amount of the organic solvent (E) is between 500 and 5000 parts by weight.

In an embodiment of the invention, the photosensitive resin composition further includes a colorant (F).

In an embodiment of the invention, based on a usage amount of 100 parts by weight of the alkali-soluble resin (A), the usage amount of the colorant (F) is 20 parts by weight to 150 parts by weight.

The invention further provides a method for manufacturing a color filter. The method includes using the photosensitive resin composition above to form a pixel layer.

The invention further provides a method for manufacturing a color filter. The method includes curing the photosensitive resin composition above to form a protective film.

The invention further provides a color filter. The color filter is formed by the method for fabricating a color filter.

The invention further provides a liquid crystal display apparatus. The liquid crystal display apparatus includes the color filter above.

Based on the above, when the alkali-soluble resin and the polysiloxane polymer of the invention are used in a photosensitive resin composition, the issues of poor high precision pattern linearity and large size of foreign matter thereof can be improved. As a result, the photosensitive resin composition of the invention is suitable for a color filter and a liquid crystal display apparatus.

To make the above features and advantages of the invention more comprehensible, several embodiments are described in detail as follows.

### DESCRIPTION OF THE EMBODIMENTS

The invention provides a photosensitive resin composition. The photosensitive resin composition includes an alkali-soluble resin (A), a polysiloxane polymer (B), a compound (C) containing an ethylenically unsaturated group, a photoinitiator (D), and an organic solvent (E). In the following, the individual components used in the photosensitive resin composition of the invention are described in detail.

### <Alkai-Soluble Resin (A)>

### Alkai-Soluble Resin (A-1)

The alkali-soluble resin (A) of the invention includes an alkali-soluble resin (A-1), and the alkali-soluble resin (A-1) is represented by formula (1):

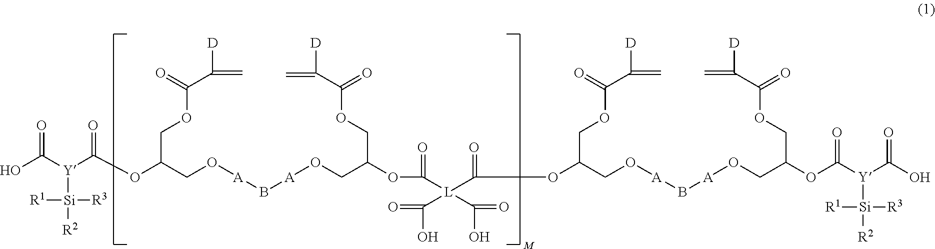

in formula (1), A represents a phenylene group, a hydrogen atom on the phenylene group can be substituted by a C1˜C5 alkyl group, a halogen atom, or a phenyl group; B represents —CO—, —SO₂—, —C(CF₃)₂—, —Si(CH₃)₂—, —CH₂—, —C(CH₃)₂—, —O—, 9,9-fluorenylidene, or a single bond; L represents a tetravalent carboxylic acid residue; Y′ represents a C1˜C20 trivalent organic group; R¹, R², and R³ are each independently a hydrogen atom, a halogen atom, or a monovalent organic group; D represents a hydrogen atom or a methyl group; and M is 1-20. Specifically, when the photosensitive resin composition of the invention does not contain the alkali-soluble resin (A-1), the high precision pattern linearity thereof is poor and the size of foreign matter thereof is greater.

The alkali-soluble resin (A-1) of the invention is obtained by reacting at least a component (a-1), a component (a-2), and a component (a-3). The component (a-1) is a diol compound containing a polymeric unsaturated group, the component (a-2) is a tetracarboxylic acid or an acid dianhydride thereof, and the component (a-3) is an dicarboxylic acid anhydride represented by formula (2):

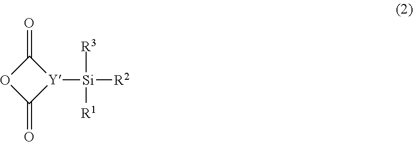

in formula (2), Y′ represents a C1˜C20 trivalent organic group, and R¹, R², and R³ are each independently a hydrogen atom, a halogen atom, or a monovalent organic group.

The component (a-1) is manufactured by reacting a mixture, and the mixture includes a bisphenol compound (a-1-i) containing two epoxy groups and a compound (a-1-ii) having at least one carboxylic acid group and at least one ethylenically unsaturated group. In addition, the mixture can also contain other compounds.

Examples of preferred bisphenol compounds for the bisphenol compound (a-1-i) containing two epoxy groups can include, for instance: bis(4-hydroxyphenyl)ketone, bis(4-hydroxy-3,5-dimethylphenyl)ketone, bis(4-hydroxy-3,5-dichlorophenyl)ketone, bis(4-hydroxyphenyl)sulfone, bis(4-hydroxy-3,5-dimethylphenyl)sulfone, bis(4-hydroxy-3,5-dichlorophenyl)sulfone, bis(4-hydroxyphenyl)hexafluoropropane, bis(4-hydroxy-3,5-dimethylphenyl)hexafluoropropane, bis(4-hydroxy-3,5-dichlorophenyl)hexafluoropropane, bis(4-hydroxyphenyl)dimethylsilane, bis(4-hydroxy-3,5-dimethylphenyl)dimethylsilane, bis(4-hydroxy-3,5-dichlorophenyl)dimethylsilane, bis(4-hydroxyphenyl)methane, bis(4-hydroxy-3,5-dichlorophenyl)methane, bis(4-hydroxy-3,5-dibromophenyl)methane, 2,2-bis(4-hydroxyphenyl)propane, 2,2-bis(4-hydroxy-3,5-dimethylphenyl)propane, 2,2-bis(4-hydroxy-3,5-dichlorophenyl)propane, 2,2-bis(4-hydroxy-3-methylphenyl)propane, 2,2-bis(4-hydroxy-3-chlorophenyl)propane, bis(4-hydroxyphenyl)ether, bis(4-hydroxy-3,5-dimethylphenyl)ether, and bis(4-hydroxy-3,5-dichlorophenyl)ether; and 9,9-bis(4-hydroxyphenyl)fluorene, 9,9-bis(4-hydroxy-3,5-dimethylphenyl)fluorene, 9,9-bis(4-hydroxy-3-chlorophenyl)fluorene, 9,9-bis(4-hydroxy-3-bromophenyl)fluorene, 9,9-bis(4-hydroxy-3-fluorophenyl)fluorene, and 9,9-bis(4-hydroxy-3,5-dimethylphenyl)fluorene.

The bisphenol compound (a-1-0 containing two epoxy groups can be obtained by, for instance, reacting the bisphenol compound and an epihalohydrin in a dehydrohalogenation reaction in the presence of an alkali metal hydroxide.

Specific examples of the epihalohydrin include: 3-chloro-1,2-epoxypropane(epichlorohydrin), 3-bromo-1,2-epoxypropane(epibromohydrin), and any combination thereof. Prior to or during the dehydrohalogenation reaction, an alkali metal hydroxide such as sodium hydroxide or potassium hydroxide can be added. The operating temperature of the dehydrohalogenation reaction is 20° C. to 120° C. and the range of the operating time thereof is 1 hour to 10 hours.

In an embodiment, the alkali metal hydroxide added to the dehydrohalogenation reaction can also be an aqueous solution thereof. Specifically, when the aqueous solution of alkali metal hydroxide is continuously added to the dehydrohalogenation reaction system, water and epihalohydrin can be continuously distilled off under reduced pressure or normal pressure to separate and remove water, and epihalohydrin can be continuously flown back to the reaction system at the same time.

Moreover, before the dehydrohalogenation reaction is performed, a quaternary ammonium salt such as tetramethyl ammonium chloride, tetramethyl ammonium bromide, or trimethyl benzyl ammonium chloride can also be added as a catalyst to react for 1 hour to 5 hours at 50° C. to 150° C., and then an alkali metal hydroxide or an aqueous solution thereof is added to react for 1 hour to 10 hours at 20° C. to 120° C. to perform the dehydrohalogenation reaction.

Based on a total equivalent of 1 equivalent of the hydroxyl group in the bisphenol compound, the usage amount of the epihalohydrin is 1 equivalent to 20 equivalents, preferably 2 equivalents to 10 equivalents. Based on a total equivalent of 1 equivalent of the hydroxyl group in the bisphenol compound, the usage amount of the alkali metal hydroxide added to the dehydrohalogenation reaction is 0.8 equivalents to 15 equivalents, preferably 0.9 equivalents to 11 equivalents.

Moreover, to facilitate the dehydrohalogenation reaction, in addition to adding an alcohol such as methanol or ethanol, an aprotic polar solvent such as dimethyl sulfone or dimethyl sulfoxide can also be added to perform the reaction. When alcohol is used, based on a total amount of 100 wt % of the epihalohydrin, the usage amount of the alcohol is 2 wt % to 20 wt %, preferably 4 wt % to 15 wt %. When an aprotic polar solvent is used, based on a total amount of 100 wt % of the epihalohydrin, the usage amount of the aprotic polar solvent is 5 wt % to 100 wt %, preferably 10 wt % to 90 wt %.

After the dehydrohalogenation reaction is complete, a rinse treatment can be optionally performed. Then, the epihalohydrin, the alcohol, and the aprotic polar solvent . . . etc. are removed by reduced pressure distillation, for example, at a temperature of 110° C. to 250° C. and a pressure less than or equal to 1.3 kPa(10 mmHg).

To prevent the epoxy resin formed from containing a hydrolyzable halogen, the solution after the dehydrohalogenation reaction can be added to a solvent such as benzene, toluene, or methyl isobutyl ketone, and then an aqueous solution of alkali metal hydroxide such as sodium hydroxide or potassium hydroxide is added to perforin the dehydrohalogenation reaction again. In the dehydrohalogenation reaction, based on a total equivalent of 1 equivalent of the hydroxyl group in the bisphenol compound, the usage amount of the alkali metal hydroxide is 0.01 mol to 1 mol, preferably 0.05 mol to 0.9 mol. Moreover, the range of the operating temperature of the dehydrohalogenation reaction is 50° C. to 120° C. and the range of the operating time thereof is 0.5 hours to 2 hours.

After the dehydrohalogenation reaction is complete, salts can be removed through steps such as filtering and rinsing. Furthermore, solvent such as benzene, toluene, or methyl isobutyl ketone can be distilled off by reduced pressure distillation to obtain the bisphenol compound (a-1-i) containing two epoxy groups.

The bisphenol compound (a-1-0 containing two epoxy groups is preferably a bisphenol compound containing two epoxy groups represented by formula (2-1) or a polymer formed by polymerizing the bisphenol compound monomer having two epoxy groups represented by formula (2-2).

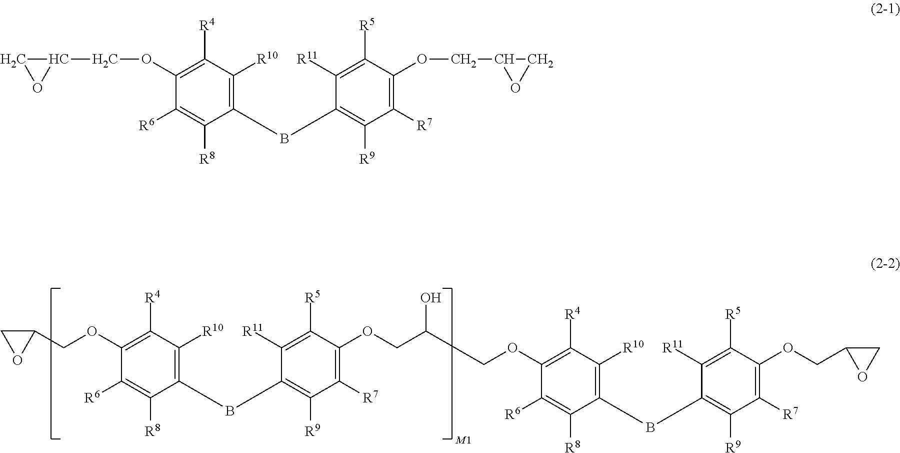

In formula (2-1) and formula (2-2), R⁴, R⁵, R⁶, R⁷, R⁸, R⁹, R¹⁰, and R¹¹ are each independently a hydrogen atom, a halogen atom, a C1˜C5 alkyl group or phenyl group, B represents —CO—, —SO₂—, —C(CF₃)₂—, —Si(CH₃)₂—, —CH₂—, —C(CH₃)₂—, —O—, 9,9-fluorenylidene, or a single bond, and M1 is preferably 1˜10, more preferably 1˜2.

The bisphenol compound containing two epoxy groups represented by formula (2-1) is preferably a bisphenol compound containing two epoxy groups represented by formula (2-3).

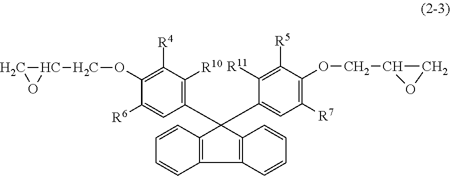

In formula (2-3), R⁴, R⁵, R⁶, R⁷, R¹⁰, and R¹¹ are each independently a hydrogen atom, a halogen atom, a C1˜C5 alkyl group, or a phenyl group.

The bisphenol compound containing two epoxy groups represented by formula (2-3) is, for instance, a bisphenol fluorene compound containing two epoxy groups obtained by reacting a bisphenol fluorene compound and epihalohydrin.

Examples of the bisphenol fluorene compound can include, for instance, compounds such as 9,9-bis(4-hydroxyphenyl)fluorene, 9,9-bis(4-hydroxy-3-methylphenyl)fluorene, 9,9-bis(4-hydroxy-3-chlorophenyl)fluorene, 9,9-bis(4-hydroxy-3-bromophenyl)fluorene, 9,9-bis(4-hydroxy-3-fluorophenyl)fluorene, 9,9-bis(4-hydroxy-3-methoxyphenyl)fluorene, 9,9-bis(4-hydroxy-3,5-dimethylphenyl)fluorene, 9,9-bis(4-hydroxy-3,5-dichlorophenyl)fluorene, and 9,9-bis(4-hydroxy-3,5-dibromophenyl)fluorene.

Examples of the epihalohydrin can include, for instance: 3-chlroro-1,2-epoxypropane and 3-bromo-1,2-epoxypropane.

The bisphenol fluorene compound having two epoxy groups includes commercial products such as: (1) products manufactured by Nippon Steel Chemical such as ESF-300; (2) products manufactured by Osaka Gas such as PG-100 and EG-210; and (3) products manufactured by S.M.S Technology Co. such as SMS-F9PhPG, SMS-F9CrG, and SMS-F914PG.

The compound (a-1-ii) having at least one carboxylic acid group and at least one ethylenically unsaturated group is at least one selected from the group consisting of the following compounds: acrylic acid, methacrylic acid, 2-methacryloyloxyethylbutanedioic acid, 2-methacryloyloxybutylbutanedioic acid, 2-methacryloyloxyethylhexanedioic acid, 2-methacryloyloxybutylhexanedioic acid, 2-methacryloyloxyethylhexahydrophthalic acid, 2-methacryloyloxyethylmaleic acid, 2-methacryloyloxypropylmaleic acid, 2-methacryloyloxybutylmaleic acid, 2-methacryloyloxypropylbutanedioic acid, 2-methacryloyloxypropylhexanedioic acid, 2-methacryloyloxypropyltetrahydrophthalic acid, 2-methacryloyloxypropylphthalic acid, 2-methacryloyloxybutylphthalic acid, and 2-methacryloyloxybutylhydrophthalic acid; a compound obtained by reacting (meth)acrylate containing a hydroxyl group and a dicarboxylic acid compound, wherein the dicarboxylic acid compound includes, but is not limited to, adipic acid, succinic acid, maleic acid, or phthalic acid; and a hemiester compound obtained by reacting (meth)acrylate containing a hydroxyl group and a carboxylic acid anhydride compound, wherein the (meth)acrylate containing a hydroxyl group includes, but is not limited to, (2-hydroxyethyl)acrylate, (2-hydroxyethyl)methacrylate, (2-hydroxypropyl)acrylate, (2-hydroxypropyl)methacrylate, (4-hydroxybutyl)acrylate, (4-hydroxybutyl)methacrylate, or pentaerythritol trimethacrylate. Moreover, the carboxylic acid anhydride compound can be at least one selected from the group consisting of the following compounds: a dicarboxylic acid anhydride compound such as butanedioic anhydride, maleic anhydride, itaconic anhydride, phthalic anhydride, tetrahydrophthalic anhydride, hexahydrophthalic anhydride, methyl tetrahydrophthalic anhydride, methyl hexahydrophthalic anhydride, methyl endo-methylene tetrahydro phthalic anhydride, chlorendic anhydride, glutaric anhydride, and 1,3-dioxoisobenzofuran-5-carboxylic anhydride; and a tetracarboxylic acid anhydride compound such as benzophenone tetracarboxylic dianhydride (BTDA for short), biphenyltetracarboxylic dianhydride, and diphenyl ether tetracarboxylic di anhydride.

The component (a-2) is at least one selected from the group consisting of saturated straight-chain hydrocarbon tetracarboxylic acid, alicyclic tetracarboxylic acid, aromatic tetracarboxylic acid, and the acid dianhydrides.

Examples of the saturated straight-chain hydrocarbon tetracarboxylic acid can include: butanetetracarboxylic acid, pentanetetracarboxylic acid, and hexanetetracarboxylic acid. The saturated straight-chain hydrocarbon tetracarboxylic acid can also have a substituent.

Examples of the alicyclic tetracarboxylic acid can include: cyclobutanetetracarboxylic acid, cyclopentanetetracarboxylic acid, cyclohexanetetracarboxylic acid, and norbornane tetracarboxylic acid. The alicyclic tetracarboxylic acid can also have a substituent.

Examples of the aromatic tetracarboxylic acid can include: pyromellitic acid, benzophenone tetracarboxylic acid, biphenyltetracarboxylic acid, diphenylether tetracarboxylic acid, diphenylsulfonetetracarboxylic acid, and 1,2,3,6-tetrahydrophthalic acid.

In the alkali-soluble resin (A-1) of the invention, the component (a-2) is preferably biphenyltetracarboxylic acid, benzophenone tetracarboxylic acid, diphenylether tetracarboxylic acid, or the acid dianhydrides thereof, and more preferably biphenyltetracarboxylic acid, diphenylether tetracarboxylic acid, or the acid dianhydrides.

The molar ratio (a-2)/(a-1) of the component (a-1) and the component (a-2) is 0.2˜1.0, preferably 0.3˜0.9, and more preferably 0.4˜0.8. When the molar ratio (a-2)/(a-1) of the component (a-1) and the component (a-2) is 0.2˜1.0, the high precision pattern linearity of the photosensitive composition is better.

The component (a-3) is the dicarboxylic anhydride represented by formula (2) above. Moreover, the component (a-3) is at least one selected from the group consisting of the following compounds: trimethoxysilylpropyl succinic anhydride, triethoxysilylpropyl succinic anhydride, methyldimethoxysilylpropyl succinic anhydride, methyldiethoxysilylpropyl succinic anhydride, trimethoxysilylbutyl succinic anhydride, triethoxysilylbutyl succinic anhydride, metyldiethoxysilylbutyl succinic anhydride, para-(trimethoxysilyl)phenyl succinic anhydride, para-(triethoxysilyl)phenyl succinic anhydride, para-(methyldimethoxysilyl)phenyl succinic anhydride, para-(methyldiethoxysilyl)phenyl succinic anhydride, meta-(trimethoxysilyl)phenyl succinic anhydride, meta-(triethoxysilyl)phenyl succinic anhydride, and meta-(metyldiethoxysilyl)phenyl succinic anhydride.

The component (a-3) is preferably at least one selected from the group consisting of the following compounds: trimethoxysilylpropyl succinic anhydride, triethoxysilylpropyl succinic anhydride, para-(trimethoxysilyl)phenyl succinic anhydride, para-(triethoxysilyl)phenyl succinic anhydride, meta-(trimethoxysilyl)phenyl succinic anhydride, and meta-(triethoxysilyl)phenyl succinic anhydride.

The molar ratio (a-3)/(a-1) of the component (a-1) and the component (a-3) is 0.02-1.6, preferably 0.05-1.4, and more preferably 0.1-1.2. When the molar ratio (a-3)/(a-1) of the component (a-1) and the component (a-3) is 0.02-1.6, the high precision pattern linearity of the photosensitive composition is better.

In addition to the component (a-1), the component (a-2), and the component (a-3), the alkali-soluble resin (A-1) of the invention can also include a component (a-4).

The component (a-4) includes dicarboxylic acid or an anhydride thereof, but does not include the component (a-3). Examples of the dicarboxylic acid can include: saturated straight-chain hydrocarbon dicarboxylic acid, saturated cyclic hydrocarbon dicarboxylic acid, and unsaturated dicarboxylic acid.

Examples of the saturated straight-chain hydrocarbon dicarboxylic acid can include succinic acid, acetyl succinic acid, adipic acid, azelaic acid, citramalic acid, malonic acid, glutaric acid, citric acid, tataric acid, ketogluconic acid, pimelic acid, sebacic acid, suberic acid, and diglycolic acid. The hydrocarbon group in the saturated straight-chain hydrocarbon dicarboxylic acid can also be substituted.

Examples of the saturated cyclic hydrocarbon dicarboxylic acid can include hexahydrophthalic acid, cyclobutanedicarboxylic acid, cyclopentanedicarboxylic acid, norbornanedicarboxylic acid, and hexahydrotrimellitic acid. The saturated cyclic hydrocarbon dicarboxylic acid can also be an alicyclic dicarboxylic acid in which a saturated hydrocarbon is substituted.

Examples of the unsaturated dicarboxylic acid can include maleic acid, itaconic acid, phthalic acid, tetrahydrophthalic acid, methyl endo-methylene tetrahydro phthalic acid, chlorendic acid, and trimellitic acid.

The dicarboxylic acids are preferably succinic acid, itaconic acid, tetrahydrophthalic acid, hexahydrotrimellitic acid, phthalic acid, or trimellitic acid, more preferably succinic acid, itaconic acid, or tetrahydrophthalic acid.

The component (a-4) is preferably succinic anhydride, itaconic anhydride, tetrahydrophthalic anhydride, hexahydrotrimellitic anhydride, phthalic anhydride, or trimellitic anhydride, more preferably succinic anhydride, itaconic anhydride, or tetrahydrophthalic anhydride.

The method for manufacturing the alkali-soluble resin (A-1) of the invention is not particularly limited. The alkali soluble resin (A-1) can be obtained as long as the component (a-1), the component (a-2), and the component (a-3) are reacted. For instance, the alkali-soluble resin (A-1) of the invention can be obtained by heating the bisphenol fluorene epoxy(meth)acrylate used as the component (a-1) in a solvent such as propylene glycol monomethyl ether acetate, and reacting the resultant with the component (a-2) and the component (a-3).

Moreover, the reaction conditions of the solvent and the catalyst used for manufacturing the component (a-1) and the alkali-soluble resin (A-1) are not particularly limited, but a solvent without a hydroxyl group and having a boiling point higher than the reaction temperature is preferred. Examples of the solvent preferably include: a cellosolve solvent such as ethyl cellosolve acetate and butyl cellosolve acetate; an ether or ester solvent having a high boiling point such as diglyme, ethylcarbitol acetate, butylcarbitol acetate, and propylene glycol monomethyl ether acetate; and a ketone solvent such as cyclohexanone and diisobutyl ketone. Moreover, examples of the catalyst can include an ammonium salt such as tetraethylammonium bromide and triethylbenzylammonium chloride, and a known phosphine catalyst such as triphenylphosphine and tris(2,6-dimethoxyphenyl)phosphine.

Moreover, the method of reacting the component (a-1), the component (a-2), the component (a-3) and/or the component (a-4) is not particularly limited. For instance, a known method of reacting a diol compound and tetracarboxylic dianhydride at a reaction temperature of 90° C.˜140° C. as described in Japanese Patent Laid-Open Publication No. 9-325494 can be used. Preferably, the component (a-1), the component (a-2), and the component (a-3) are reacted in a manner that ends of the compound is a carboxyl group and are quantitatively reacted in a manner that a molar ratio (a-1):(a-2):(a-3):(a-4)=1:0.2˜1:0.02˜1.6:0˜0.3. Moreover, preferably, the components are uniformly dissolved and reacted at a reaction temperature of 90° C.-130° C. and then reacted and aged at a reaction temperature of 40° C. −80° C.

The number-average molecular weight (Mn) of the alkali-soluble resin (A-1) of the invention represented by formula (1) measured by gel permeation chromatography (GPC) is, in polystyrene equivalent, preferably greater than or equal to 1000 and less than or equal to 10,000. When the number-average molecular weight of the alkai-soluble resin (A-1) represented by formula (1) is less than 1000, degradation of alkali resistance may result, causing a gap in a pattern due to alkali development after a photohardening process and significant reduction in reproducibility of a fine line pattern. When the number-average molecular weight is greater than 10,000, poor developability after development readily occurs.

### Alkai-Soluble Resin (A-2)

The alkali-soluble resin (A) of the invention can further include an alkali-soluble resin (A-2) other than the alkali-soluble resin (A-1), and the alkali-soluble resin (A-2) is obtained through the polymerization reaction of a mixture. In particular, the mixture includes the epoxy compound (a-i) having at least two epoxy groups and the compound (a-ii) having at least one carboxylic acid group and at least one ethylenically unsaturated group. Moreover, the mixture can further optionally include a carboxylic acid anhydride compound (a-iii) and/or a compound (a-iv) containing an epoxy group.

Moreover, when the photosensitive resin composition of the invention contains the alkali-soluble resin (A-2), the high precision pattern linearity thereof is better. In the photosensitive resin composition of the invention, when the weight ratio of the alkali-soluble resin (A-1) and the alkali-soluble resin (A-2) is between 10/90 and 100/0, the high precision pattern linearity thereof is better.

Specifically, the epoxy compound (a-i) having at least two epoxy groups has the structure represented by formula (3) or formula (4). The description of “the epoxy compound (a-i) having at least two epoxy groups has the structure represented by formula (3) or formula (4)” also includes the condition in which the compound having the structure represented by formula (3) and the compound having the structure represented by formula (4) are both present and act as the epoxy compound (a-i) having at least two epoxy groups. Specifically, the epoxy compound (a-i) having at least two epoxy groups has the structure represented by formula (3):

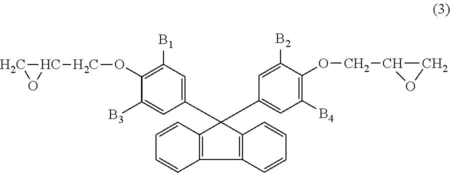

in formula (3), B₁, B₂, B₃, and B₄ can be the same or different from one another, and B₁, B₂, B₃, and B₄ respectively represent a hydrogen atom, a halogen atom, a C1˜C5 alkyl group, a C1˜C5 alkoxy group, a C6˜C12 aryl group, or a C6˜C12 aralkyl group.

The epoxy compound (a-i) having at least two epoxy groups having the structure represented by formula (3) can include, but is not limited to, a bisphenol fluorene compound containing an epoxy group obtained by reacting a bisphenol fluorene compound and epihalohydrin.

Specific examples of the bisphenol fluorene compound can include, but is not limited to: 9,9-bis(4-hydroxyphenyl)fluorene, 9,9-bis(4-hydroxy-3-methylphenyl)fluorene, 9,9-bis(4-hydroxy-3-chlorophenyl)fluorene, 9,9-bis(4-hydroxy-3-bromophenyl)fluorene, 9,9-bis(4-hydroxy-3-fluorophenyl)fluorene, 9,9-bis(4-hydroxy-3-methoxyphenyl)fluorene, 9,9-bis(4-hydroxy-3,5-dimethylphenyl)fluorene, 9,9-bis(4-hydroxy-3,5-dichlorophenyl)fluorene, and 9,9-bis(4-hydroxy-3,5-dibromophenyl)fluorene.

The epihalohydrin can include, but is not limited to, 3-chlroro-1,2-epoxypropane or 3-bromo-1,2-epoxypropane.

Specific examples of the bisphenol fluorene compound containing an epoxy group obtained by reacting a bisphenol fluorene compound and epihalohydrin can include, but are not limited to: products manufactured by Nippon Steel Chemical Co., Ltd. such as ESF-300; products manufactured by Osaka Gas Co., Ltd. such as PG-100 and EG-210; and products manufactured by S.M.S Technology Co., Ltd. such as SMS-F9PhPG, SMS-F9CrG, and SMS-F914PG.

The epoxy compound (a-i) having at least two epoxy groups can also have the structure represented by formula (4):

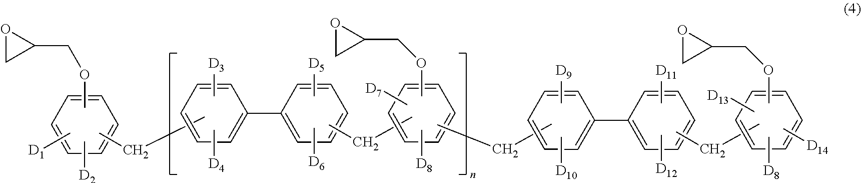

in formula (4), D₁ to D₁₄ can be the same or different from one another, D₁ to D₁₄ respectively represent a hydrogen atom, a halogen atom, a C1˜C8 alkyl group, or a C6˜C15 aromatic group, and n can represent an integer of 0˜10.

The epoxy compound (a-i) having at least two epoxy groups having the structure represented by formula (4) can be obtained by reacting a compound having the structure represented by formula (4-1) and epihalohydrin in the presence of an alkali metal hydroxide:

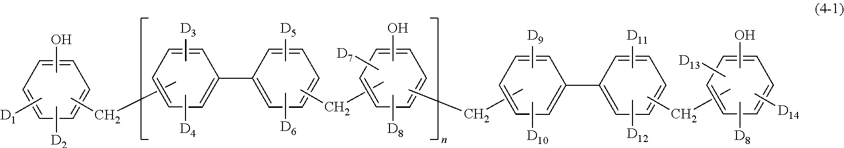

in formula (4-1), the definition of each of D₁ to D₁₄ and n is as described above and is not repeated herein.

Moreover, the epoxy compound (a-i) having at least two epoxy groups represented by formula (4) can also be formed by the following steps. First, a condensation reaction is performed between a compound having the structure represented by formula (4-2) and a phenol in the presence of an acid catalyst to form the compound having the structure represented by formula (4-1). Then, an excessive amount of epihalohydrin is added to perform a dehydrohalogenation reaction to obtain the epoxy compound (a-i) having at least two epoxy groups represented by formula (4):

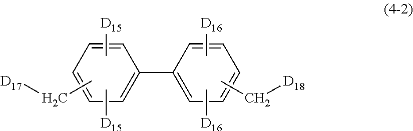

in formula (4-2), D₁₅ and D₁₆ can be the same or different from each other, and D₁₅ and D₁₆ can represent a hydrogen atom, a halogen atom, a C1˜C8 alkyl group, or a C6˜C15 aromatic group; D₁₇ and D₁₈ can be the same or different from each other, and D₁₇ and D₁₈ can represent a halogen atom, a C1˜C6 alkyl group, or a C1˜C6 alkoxy group. Preferably, the halogen atom can be a chlorine atom or a bromine atom, the alkyl group can be a methyl group, an ethyl group, or a tertiary butyl group, and the alkoxy group can be a methoxy group or an ethoxy group.

The phenol can include, but is not limited to: phenol, cresol, ethylphenol, n-propylphenol, isobutylphenol, t-butylphenol, octylphenol, nonylphenol, xylenol, methylbutylphenol, di-t-butylphenol, vinylphenol, propenylphenol, ethinylphenol, cyclopentylphenol, cyclohexylphenol, or cyclohexylcresol. Moreover, the phenol can be used alone or in multiple combinations of a plurality of the aforementioned compounds.

Based on a usage amount of 1 mol of the compound having the structure represented by formula (4-2), the usage amount of the phenol is 0.5 mol to 20 mol and preferably 2 mol to 15 mol.

Specific examples of the acid catalyst include: hydrochloric acid, sulfuric acid, p-toluenesulfonic acid, oxalic acid, boron trifluoride, aluminium chloride anhydrous, and zinc chloride. Moreover, the acid catalyst is preferably p-toluenesulfonic acid, sulfuric acid, or hydrochloric acid. Moreover, the acid catalyst can be used alone or in multiple combinations of a plurality of the aforementioned compounds.

The usage amount of the acid catalyst is not particularly limited. However, based on a usage amount of 100 weight percent (wt %) of the compound having the structure represented by formula (4-2), the usage amount of the acid catalyst is preferably 0.1 wt % to 30 wt %.

The condensation reaction can be performed without a solvent or in the presence of an organic solvent. Specific examples of the organic solvent can include, but are not limited to, toluene, xylene, and methyl isobutyl ketone. Moreover, the organic solvent can be used alone or in multiple combinations of a plurality of the aforementioned compounds.

Based on a total weight of 100 wt % of the compound having the structure represented by formula (4-2) and the phenol, the usage amount of the organic solvent is 50 wt % to 300 wt %, preferably 100 wt % to 250 wt %. The operating temperature of the condensation reaction is 40° C. to 180° C. and the operating time of the condensation reaction is 1 hour to 8 hours.

After the condensation reaction is complete, a neutralization treatment or a rinse treatment can be performed on the reaction solution. In the neutralization treatment, the pH of the reaction solution is adjusted to pH 3 to pH 7, preferably pH 5 to pH 7. The rinse treatment can be performed by using a neutralizer. The neutralizer is an alkaline substance and specific examples thereof can include, but is not limited to, alkali metal hydroxides such as sodium hydroxide and potassium hydroxide; alkaline earth metal hydroxides such as calcium hydroxide and magnesium hydroxide; organic amines such as diethylene triamine, triethylenetetramine, aniline, and phenylene diamine; ammonia and sodium dihydrogen phosphate. Moreover, the rinse treatment can be performed with a known method. For instance, an aqueous solution containing a neutralizer is added to the reaction solution. Next, extraction is performed repeatedly. After the neutralization treatment or the rinse treatment, the unreacted phenol and solvent are distilled off through a heat treatment under reduced pressure, and then condensation is performed to obtain a compound having the structure represented by formula (4-1).

Specific examples of the epihalohydrin include: 3-chloro-1,2-epoxypropane, 3-bromo-1,2-epoxypropane, and any combination thereof. Before the dehydrohalogenation reaction is performed or during the reaction process, an alkali metal hydroxide such as sodium hydroxide or potassium hydroxide can be added to the reaction solution. Moreover, the temperature of the dehydrohalogenation reaction is 20° C. to 120° C. and the time thereof is 1 hour to 10 hours.

In an embodiment, the alkali metal hydroxide added can also be an aqueous solution of alkali metal hydroxide. Specifically, when the aqueous solution of alkali metal hydroxide is continuously added to the dehydrohalogenation reaction system, water and epihalohydrin can be distilled off under reduced pressure or normal pressure. Therefore, water is removed and epihalohydrin is continuously flown back to the reaction system at the same time.

Moreover, before the dehydrohalogenation reaction is performed, a quaternary ammonium salt such as tetramethyl ammonium chloride, tetramethyl ammonium bromide, or trimethyl benzyl ammonium chloride can be added to the reaction system as a catalyst to react for 1 hour to 5 hours at 50° C. to 150° C. Then, alkali metal hydroxide or an aqueous solution thereof is added to react for 1 hour to 10 hours at 20° C. to 120° C. to perform the dehydrohalogenation reaction.

Based on a total equivalent of 1 equivalent of the hydroxyl group in the compound having the structure represented by formula (4-1), the usage amount of the epihalohydrin can be 1 equivalent to 20 equivalents, preferably 2 equivalents to 10 equivalents. Based on a total equivalent of 1 equivalent of the hydroxyl group in the compound having the structure represented by formula (4-1), the usage amount of the alkali metal hydroxide added to the dehydrohalogenation reaction can be 0.8 equivalents to 15 equivalents, preferably 0.9 equivalents to 11 equivalents.

Moreover, to facilitate the dehydrohalogenation reaction, in addition to adding an alcohol such as methanol or ethanol, an aprotic polar solvent such as dimethyl sulfone or dimethyl sulfoxide can also be added to perform the reaction. When an alcohol is used, based on a total usage amount of 100 wt % of the epihalohydrin, the usage amount of the alcohol can be 2 wt % to 20 wt %, preferably 4 wt % to 15 wt %. Based on a total amount of 100 wt % of the epihalohydrin, the usage amount of the aprotic polar solvent can be 5 wt % to 100 wt %, preferably 10 wt % to 90 wt %.

After the dehydrohalogenation reaction is complete, a rinse treatment can be optionally performed. Then, the epihalohydrin, the phenol, and the aprotic polar solvent . . . etc. are removed by reduced pressure distillation. The reduced pressure distillation can be performed, for instance, at a temperature of 110° C. to 250° C. and a pressure less than or equal to 1.3 kPa(10 mmHg).

To prevent the epoxy resin formed from having a hydrolyzable halogen, a solvent such as toluene or methyl isobutyl ketone can be added to the solution after the dehydrohalogenation reaction, and then an aqueous solution of alkali metal hydroxide such as sodium hydroxide or potassium hydroxide is added to perform the dehydrohalogenation reaction again. In the dehydrohalogenation reaction, based on a total equivalent of 1 equivalent of the hydroxyl group in the compound having the structure represented by formula (4-1), the usage amount of the alkali metal hydroxide is 0.01 mol to 0.3 mol, preferably 0.05 mol to 0.2 mol. Moreover, the temperature of the dehydrohalogenation reaction is 50° C. to 120° C. and the time thereof is 0.5 hours to 2 hours.

After the dehydrohalogenation reaction is complete, salts in the reaction solution can be removed through steps such as filtering and rinsing, and solvents such as toluene and methyl isobutyl ketone can be removed through a reduced pressure distillation to obtain the epoxy compound (a-i) having at least two epoxy groups having the structure represented by formula (4). The epoxy compound (a-i) having at least two epoxy groups having the structure represented by formula (4) can include, but is not limited to, a product such as NC-3000, NC-3000H, NC-3000S, or NC-3000P manufactured by Nippon Kayaku Co. Ltd.

The compound (a-ii) having at least one carboxylic acid group and at least one ethylenically unsaturated group is selected from the group consisting of (1) to (3): (1) acrylate, methacrylate, 2-methacryloyloxyethylbutanedioic acid, 2-methacryloyloxybutylbutanedioic acid, 2-methacryloyloxyethylhexanedioic acid, 2-methacryloyloxybutylhexanedioic acid, 2-methacryloyloxyethylhexahydrophthalic acid, 2-methacryloyloxyethylmaleic acid, 2-methacryloyloxypropylmaleic acid, 2-methacryloyloxybutylmaleic acid, 2-methacryloyloxypropylbutanedioic acid, 2-methacryloyloxypropylhexanedioic acid, 2-methacryloyloxypropyltetrahydrophthalic acid, 2-methacryloyloxypropylphthalic acid, 2-methacryloyloxybutylphthalic acid, and 2-methacryloyloxybutylhydrophthalic acid; (2) a compound obtained by reacting (meth)acrylic acid containing a hydroxyl group and a dicarboxylic acid compound, wherein the dicarboxylic acid compound can include, but is not limited to, hexanedioic acid, butanedioic acid, maleic acid, or phthalic acid; and (3) a half ester compound obtained by reacting (meth)acrylic acid containing a hydroxyl group and the carboxylic acid anhydride compound (a-iii), wherein the (meth)acrylic acid containing a hydroxyl group can include, but is not limited to, (2-hydroxyethyl) acrylate, (2-hydroxyethyl) methacrylate, (2-hydroxypropyl) acrylate, (2-hydroxypropyl) methacrylate, (4-hydroxybutyl) acrylate, (4-hydroxybutyl) methacrylate, or pentaerythritol trimethacrylate. Moreover, the carboxylic acid anhydride compound can be the same as the carboxylic acid anhydride compound (a-iii) that may be contained in the mixture of the alkali-soluble resin (A-2), which is described in the following.

As described above, the mixture of the alkali-soluble resin (A-2) can further optionally include the carboxylic acid anhydride compound (a-iii) and/or the compound (a-iv) containing an epoxy group. The carboxylic acid anhydride compound (a-iii) can be selected from the group consisting of (1) to (2): (1) dicarboxylic acid anhydride compounds such as butanedioic anhydride, maleic anhydride, itaconic anhydride, phthalic anhydride, tetrahydrophthalic anhydride, hexahydrophthalic anhydride, methyl tetrahydrophthalic anhydride, methyl hexahydrophthalic anhydride, methyl endo-methylene tetrahydro phthalic anhydride, chlorendic anhydride, glutaric anhydride, and 1,3-dioxoisobenzofuran-5-carboxylic anhydride; and (2) tetracarboxylic acid anhydride compounds such as benzophenone tetracarboxylic dianhydride, biphenyltetracarboxylic dianhydride, and diphenyl ether tetracarboxylic acid dianhydride.

The compound (a-iv) having an epoxy group is selected from the group consisting of glycidyl methacrylate, 3,4-epoxycyclohexyl methacrylate, a glycidyl ether compound containing an unsaturated group, an unsaturated compound having an epoxy group, and any combination thereof. The glycidyl ether compound containing an unsaturated group can include, but is not limited to: a product manufactured by Nagase Kasei Kogyo Co., Ltd. such as Denacol EX-111, Denacol EX-121, Denacol EX-141, Denacol EX-145, Denacol EX-146, Denacol EX-171, or Denacol EX-192.

In an embodiment, the alkali-soluble resin (A-2) can be a reaction product containing a hydroxyl group fainted by polymerizing the epoxy compound (a-i) having at least two epoxy groups and the compound (a-ii) having at least one carboxylic acid group and at least one ethylenically unsaturated group. In particular, the epoxy compound (a-i) having at least two epoxy groups has the structure represented by formula (3). Then, the carboxylic acid anhydride compound (a-iii) is added to the reaction solution to perform a polymerization reaction. Based on a total equivalent of 1 equivalent of the hydroxyl group of the reaction product containing a hydroxyl group, the equivalent of the acid anhydride group contained in the carboxylic acid anhydride compound (a-iii) is preferably 0.4 equivalents to 1 equivalent, more preferably 0.75 equivalents to 1 equivalent. When a plurality of the carboxylic acid anhydride compounds (a-iii) are used, the carboxylic acid anhydride compounds can be added to the reaction in sequence or at the same time. When a dicarboxylic acid anhydride compound and a tetracarboxylic acid anhydride compound are used as the carboxylic acid anhydride compound (a-iii), the molar ratio of the dicarboxylic acid anhydride compound and the tetracarboxylic acid anhydride compound is preferably 1/99 to 90/10, more preferably 5/95 to 80/20. Moreover, the operating temperature of the reaction can be 50° C. to 130° C.

In another embodiment, the alkali-soluble resin (A-2) can be a reaction product containing a hydroxyl group formed by reactiing the epoxy compound (a-i) having at least two epoxy groups and the compound (a-ii) having at least one carboxylic acid group and at least one ethylenically unsaturated group. In particular, the epoxy compound (a-i) having at least two epoxy groups has the structure represented by formula (3). Then, the carboxylic acid anhydride compound (a-iii) and/or the compound (a-iv) containing an epoxy group is added to the reaction solution to perform a polymerization reaction. Based on a total equivalent of 1 equivalent of the epoxy groups in the epoxy compound (a-i) having at least two epoxy groups having the structure represented by formula (a-3), the equivalent of the acid value of the compound (a-ii) having at least one carboxylic acid group and at least one ethylenically unsaturated group is preferably 0.8 equivalents to 1.5 equivalents, more preferably 0.9 equivalents to 1.1 equivalents. Based on a total usage amount of 100 mole percent (mol %) of the hydroxyl group of the reaction product containing a hydroxyl group, the usage amount of the carboxylic acid anhydride compound (a-iii) is 10 mol % to 100 mol %, preferably 20 mol % to 100 mol %, and more preferably 30 mol % to 100 mol %.

When preparing the alkali-soluble resin (A-2), to reduce the reaction time, an alkali compound is generally added to the reaction solution as a reaction catalyst. The reaction catalyst can include, but is not limited to, triphenyl phosphine, triphenyl stibine, triethylamine, triethanolamine, tetramethylammonium chloride, or benzyltriethylammonium chloride. Moreover, the reaction catalyst can be used alone or in multiple combinations of a plurality of the aforementioned compounds.

Based on a total usage amount of 100 parts by weight of the epoxy compound (a-i) having at least two epoxy groups and the compound (a-ii) having at least one carboxylic acid group and at least one ethylenically unsaturated group, the usage amount of the reaction catalyst is preferably 0.01 parts by weight to 10 parts by weight, more preferably 0.3 parts by weight to 5 parts by weight.

Moreover, to control the degree of polymerization, a polymerization inhibitor is generally added to the reaction solution. The polymerization inhibitor can include, but is not limited to, methoxyphenol, methylhydroquinone, hydroquinone, 2,6-di-t-butyl-p-cresol, or phenothiazine. Moreover, the polymerization inhibitor can be used alone or in multiple combinations of a plurality of the aforementioned compounds.

Based on a total usage amount of 100 parts by weight of the epoxy compound (a-i) having at least two epoxy groups and the compound (a-ii) having at least one carboxylic acid group and at least one ethylenically unsaturated group, the usage amount of the polymerization inhibitor is preferably 0.01 parts by weight to 10 parts by weight and more preferably 0.1 parts by weight to 5 parts by weight.

When preparing the alkali-soluble resin (A-2), a polymerization solvent can optionally be used. The polymerization solvent can include, but is not limited to: an alcohol solvent such as ethanol, propanol, isopropanol, butanol, isobutanol, 2-butanol, hexanol, or ethylene glycol; a ketone solvent such as methyl ethyl ketone or cyclohexanone; an aromatic hydrocarbon solvent such as toluene or xylene; a cellosolve solvent such as cellosolve or butyl cellosolve; a carbitol solvent such as carbitol or butyl carbitol; a propylene glycol alkyl ether solvent such as propylene glycol monomethyl ether; a poly(propylene glycol) alkyl ether solvent such as di(propylene glycol) methyl ether; an acetate solvent such as ethyl acetate, butyl acetate, ethylene glycol monoethyl ether acetate, or propylene glycol monomethyl ether acetate; an alkyl lactate solvent such as ethyl lactate or butyl lactate; or dialkyl glycol ethers. Moreover, the polymerization solvent can be used alone or in multiple combinations of a plurality of the aforementioned compounds. Moreover, the acid value of the alkali-soluble resin (A-2) is preferably 50 mgKOH/g to 200 mgKOH/g, more preferably 60 mgKOH/g to 150 mgKOH/g.

### Alkai-Soluble Resins (A-3)

The alkali-soluble resin (A) of the invention can optionally include other alkai-soluble resins (A-3). The other alkali-soluble resins (A-3) can include, but are not limited to, resins containing a carboxylic acid group or a hydroxyl group. Specifically, specific examples of the other alkali-soluble resins (A-3) can include: resins other than the alkali-soluble resin (A-1) and the alkali-soluble resin (A-2) such as an acrylic-based resin, a urethane-based resin, and a novolac resin.

### Polysiloxane Polymer (B)

The polysiloxane polymer (B) of the invention is a copolymer obtained through the hydrolysis and the partial condensation of a silane monomer. In particular, the silane monomer includes the compound represented by formula (5):

Si(R¹²)ₜ(OR¹³)₄₋ₜ (5)

wherein t is an integer of 0˜3, and when t represents 2 or 3, a plurality of R¹²s can be the same or different from one another; R¹² represents a hydrogen atom, a C1˜C10 alkyl group, a C2˜C10 alkenyl group, a C6˜C15 aromatic group, an acid anhydride substituted C1˜C10 alkyl group, an epoxy group substituted C1˜C10 alkyl group, or an epoxy group substituted alkoxy group; R¹³ represents a hydrogen atom, a C1˜C6 alkyl group, a C1˜C6 acyl group, or a C6˜C15 aromatic group, and when 4-t represents 2 or 3, a plurality of R¹³s can be the same or different from one another. Moreover, at least one R¹² represents an acid anhydride group substituted C1˜C10 alkyl group, an epoxy group substituted C1˜C10 alkyl group, or an epoxy group substituted alkoxy group. However, the invention is not limited thereto. In other embodiments, the polysiloxane polymer (B) can also optionally be obtained by performing a hydrolysis and a partial condensation using a polysiloxane or the combination of a silane monomer and a polysiloxane. In other words, the type of the polysiloxane polymer (B) is not particularly limited, provided the object of the invention can be achieved.

In the photosensitive resin composition of the invention, when the polysiloxane polymer (B) is not included, the high precision pattern linearity of the photosensitive resin composition is poor. Moreover, in the photosensitive resin composition of the invention, when the polysiloxane polymer (B) is a copolymer obtained through the hydrolysis and the partial condensation of the silane monomer represented by formula (5), the photosensitive resin composition has the advantage of smaller size of foreign matter.

Specifically, in the definition of R¹², the C1˜C10 alkyl group includes, but is not limited to: a methyl group, an ethyl group, an n-propyl group, an isopropyl group, an n-butyl group, a tertiary butyl group, an n-hexyl group, an n-decyl group, a trifluoromethyl group, 3,3,3-trifluoro-propyl, 3-aminopropyl, 3-mercaptopropyl, or 3-isocyanatepropyl. The C2˜C10 alkenyl group includes, but is not limited to: a vinyl group, 3-acryloyl-propyl, or 3-methyl-acryloyloxy-propyl. The C6˜C15 aromatic group includes, but is not limited to: a phenyl group, a tolyl group, p-hydroxyphenyl, 1-(p-hydroxyphenyl)ethyl, 2-(p-hydroxyphenyl)ethyl, 4-hydroxy-5-(p-hydroxyphenylcarbonyloxy)pentyl, or a naphthyl group. The acid anhydride group substituted C1˜C10 alkyl group includes, but is not limited to, ethyl succinic anhydride, propyl succinic anhydride, or propyl glutaric anhydride. The epoxy group substituted C1˜C10 alkyl group includes, but is not limited to, oxetanylpentyl or 2-(3,4-epoxycyclohexyl)ethyl. The epoxy group substituted alkoxy group includes, but is not limited to, glycidoxypropyl or 2-oxetanylbutoxy.

In the definition of R¹³, the C1˜C6 alkyl group includes, but is not limited to, a methyl group, an ethyl group, an n-propyl group, an isopropyl group, or an n-butyl group. The C1˜C6 acyl group includes, but is not limited to, an acetyl group. The C6˜C15 aromatic group includes, but is not limited to, a phenyl group.

Moreover, in formula (5), when t represents an integer of 0-3, t=0 represents the silane monomer is a tetrafunctional silane, t=1 represents the silane monomer is a trifunctional silane, t=2 represents the silane monomer is a difunctional silane, and t=3 represents the silane monomer is a monofunctional silane.

Specific examples of the silane monomer include, but are not limited to: (1) a tetrafunctional silane such as tetramethoxysilane, tetraethoxysilane, tetraacetoxysilane, or tetraphenoxy silane; (2) a trifunctional silane such as methyltrimethoxysilane (MTMS for short), methyltriethoxysilane, methyltriisopropoxysilane, methyltri-n-butoxysilane, ethyltrimethoxysilane, ethyltriethoxysilane, ethyltriisopropoxysilane, ethyltri-n-butoxysilane, n-propyltrimethoxysilane, n-propyltri ethoxysilane, n-butyltrimethoxysilane, n-butyltriethoxysilane, n-hexyltrimethoxysilane, n-hexyltriethoxysilane, decyltrimethoxysilane, vinyltrimethoxysilane, vinyltriethoxysilane, 3-acryoyloxypropyltrimethoxysilane, 3-methylacryloyloxypropyltrimethoxysilane, 3-methylacryloyloxypropyltriethoxysilane, phenyltrimethoxysilane (PTMS for short), phenyltriethoxysilane (PTES for short), p-hydroxyphenyltrimethoxysilane, 1-(p-hydroxyphenypethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltrimethoxysilane, trifluoromethyltriethoxysilane, 3,3,3-trifluoropropyltrimethoxysilane, 3-aminopropyltrimethoxysilane, 3-aminopropyltriethoxysilane, 3-glycidoxypropyltrimethoxysilane, 3-glycidoxypropyltriethoxysilane, 2-(3,4-epoxycyclohexyl)ethyltrimethoxysilane, 3-mercaptopropyltrimethoxysilane, 3-ethyl-3-[(3-(triphenoxysilyl)propoxy)methyl]oxetane, commercial products manufactured by Toagosei Co, Ltd.: 3-ethyl-3-[(3-(trimethoxysilyl)propoxy)methyl]oxetane (product name: TMSOX-D), 3-ethyl-3-[(3-(triethoxysilyl)propoxy)methyl]oxetane (product name: TESOX-D), 2-(trimethoxysilyl) ethyl succinic anhydride, 3-triphenoxysilyl propyl succinic anhydride, commercial products manufactured by Shin-Etsu Chemical: 3-(trimethoxysilyl) propyl succinic anhydride (product name: X-12-967), commercial products manufactured by WACKER company: 3-(triethoxysilyl) propyl succinic anhydride (product name: GF-20), 3-(trimethoxysilyl) propyl glutaric anhydride (TMSG for short), 3-(triethoxysilyl) propyl glutaric anhydride, or 3-(triphenoxysilyl) propyl glutaric anhydride; (3) a difunctional silane such as dimethyldimethoxysilane (DMDMS for short), dimethyldiethoxysilane, dimethyldiacetyloxysilane, di-n-butyldimethoxysilane, diphenyldimethoxysilane, diisopropoxy-di(2-oxetanylpropylbutoxypropyl)silane (DIDOS for short), di(3-oxetanylpentyl)dimethoxy silane, (di-n-butoxysilyl) di(propyl succinic anhydride), or (dimethoxysilyl) di(ethyl succinic anhydride); and (4) a monofunctional silane such as trimethylmethoxysilane, tri-n-butylethoxysilane, 3-glycidoxypropyldimethylmethoxysilane, 3-glycidoxypropyldimethylethoxysilane, di(2-oxetanylbutoxypentyl)-2-oxetanylpentylethoxysilane, tri(2-oxetanylpentyl)methoxy silane, (phenoxysilyl) tri(propyl succinic anhydride), or (methoxysilyl) di(ethyl succinic anhydride). Moreover, the various silane monomers can be used alone or in multiple combinations of a plurality of the aforementioned compounds.

Moreover, as described above, in addition to the silane monomer represented by formula (5) used to form the polysiloxane polymer (B), the polysiloxane polymer (B) can also be formed by the polysiloxane represented by formula (5-1):

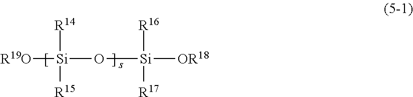

in formula (5-1), R¹⁴, R¹⁵, R¹⁶, and R¹⁷ can be the same or different from one another, and R¹⁴, R¹⁵, R¹⁶, and R¹⁷ respectively represent a hydrogen atom, a C1˜C10 alkyl group, a C2˜C10 alkenyl group, or a C6˜C15 aromatic group. In particular, any one of the alkyl group, the alkenyl group, and the aromatic group can optionally contain a substituent; when s is an integer of 2 to 1000, each R¹⁴ can be the same or different from one another, and each R¹⁵ can be the same or different from one another. In the definition of each of R¹⁴, R¹⁵, R¹⁶, and R¹⁷, the alkyl group includes, but is not limited to, a methyl group, an ethyl group, or an n-propyl group; the alkenyl group includes, but is not limited to, a vinyl group, acryoyloxypropyl, or methacryoyloxypropyl; and the aromatic group includes, but is not limited to, a phenyl group, a tolyl group, or a naphthyl group.

Moreover, in formula (5-1), R¹⁸ and R¹⁹ respectively represent a hydrogen atom, a C1˜C6 alkyl group, a C1-C6 acyl group, or a C6˜C15 aromatic group. In particular, any one of the alkyl group, the acyl group, and the aromatic group can optionally contain a substituent. In the definition of each of R¹⁸ and R¹⁹, the alkyl group can include, but is not limited to, a methyl group, an ethyl group, an n-propyl group, an isopropyl group, or an n-butyl group; the acyl group can include, but is not limited to, an acetyl group; and the aromatic group can include, but is not limited to, a phenyl group.

Moreover, in formula (5-1), s is an integer of 1 to 1000. Preferably, s is an integer of 3 to 300. More preferably, s is an integer of 5 to 200.

The polysiloxane represented by formula (5-1) can be used alone or in multiple combinations, and the polysiloxane represented by formula (5-1) includes, but is not limited to: 1,1,3,3-tetramethyl-1,3-dimethoxydisiloxane, 1,1,3,3-tetramethyl-1,3-diethoxydisiloxane, 1,1,3,3-tetraethyl-1,3-diethoxydisiloxane, a commercial product of silanol terminal polysiloxane manufactured by Gelest, Inc. such as DM-S12 (molecular weight of 400 to 700), DMS-S15 (molecular weight of 1500 to 2000), DMS-S21 (molecular weight of 4200), DMS-S27 (molecular weight of 18000), DMS-S31 (molecular weight 26000), DMS-S32 (molecular weight of 36000), DMS-S33 (molecular weight of 43500), DMS-S35 (molecular weight of 49000), DMS-S38 (molecular weight of 58000), DMS-S42 (molecular weight of 77000), or PDS-9931 (molecular weight of 1000 to 1400).

Moreover, when the silane monomer and the polysiloxane are used in combination, the mixing ratio thereof is not particularly limited. In an embodiment, the molar ratio of the silicon atoms of the silane monomer and the polysiloxane is between 100:0.01 and 50:50.

The polysiloxane polymer (B) not only can be obtained through a hydrolysis and a partial condensation of the silane monomer and/or the polysiloxane, but can also be obtained through a copolymerization by mixing the silane monomer and/or the polysiloxane with silicon dioxide particles. The average particle diameter of the silicon dioxide particles is not particularly limited. The range thereof can be 2 nm to 250 nm, preferably 5 nm to 200 nm, more preferably 10 nm to 100 nm.

The silicon dioxide particles can be used alone or in multiple combinations. The silicon dioxide particles include, but are not limited to: a commercial product manufactured by Catalysts & Chemicals Co., Ltd. such as OSCAR 1132 (particle diameter is 12 nm; dispersant is methanol), OSCAR 1332 (particle diameter is 12 nm; dispersant is n-propanol), OSCAR 105 (particle diameter is 60 nm; dispersant is γ-butyrolactone), or OSCAR 106 (particle diameter is 120 nm; dispersant is diacetone alcohol); a commercial product manufactured by Fuso Chemical Co. such as Quartron PL-1-IPA (particle diameter is 13 nm; dispersant is isopropanone), Quartron PL-1-TOL (particle diameter is 13 nm; dispersant is toluene), Quartron PL-2L-PGME (particle diameter is 18 nm; dispersant is propylene glycol monomethyl ether), or Quartron PL-2L-MEK (particle size is 18 nm; dispersant is methyl ethyl ketone); or a commercial product manufactured by Nissan Chemical Company such as IPA-ST (particle diameter is 12 nm; dispersant is isopropanol), EG-ST (particle diameter is 12 nm; dispersant is ethylene glycol), IPA-ST-L (particle size is 45 nm; dispersant is isopropanol), or IPA-ST-ZL (particle diameter is 100 nm; dispersant is isopropyl alcohol).

When the silicon dioxide particles and the silane monomer and/or the polysiloxane are mixed, the usage amounts are not particularly limited. In an embodiment, the molar ratio of silicon atoms in the silicon dioxide particles and silicon atoms in the polysiloxane are between 1% and 50%.

In general, a conventional method can be used for the polymerization reaction (i.e. hydrolysis and partial condensation) of the silane monomer, the polysiloxane and/or the silicon dioxide particles. For instance, a solvent, water, or optionally a catalyst can be added to a mixture of the silane monomer and/or the polysiloxane and/or the silicon dioxide particles, and then the mixture is heated and stirred at 50° C. to 150° C. for 0.5 hours to 120 hours. When stirring, byproducts such as alcohol and water can further be removed by distillation.

The solvent is not particularly limited, and can be the same with or different from the organic solvent (E) included in the photosensitive resin composition of the invention. In an embodiment, based on a total amount of 100 grams of the silane monomer and/or the polysiloxane, the range of the usage amount of the solvent is preferably 15 g to 1200 g, more preferably 20 g to 1100 g, and even more preferably 30 g to 1000 g.

Based on 1 mol of the hydrolyzable groups of the silane monomer, the polysiloxane and/or the silicon dioxide particles, the range of the usage amount of water used in the polymerization reaction (i.e., water used in hydrolysis) is 0.5 mol to 2 mol.

The catalyst is not particularly limited, and is preferably selected from an acidic catalyst or a basic catalyst. The acidic catalyst includes, but is not limited to, hydrochloric acid, nitric acid, sulfuric acid, hydrofluoric acid, oxalic acid, phosphoric acid, acetic acid, trifluoroacetic acid, formic acid, polybasic carboxylic acid or an anhydride thereof, or an ion exchange resin. The basic catalyst includes, but is not limited to, diethylamine, triethylamine, tripropylamine, tributylamine, tripentylamine, trihexylamine, triheptylamine, trioctylamine, diethanolamine, triethanolamine, sodium hydroxide, potassium hydroxide, alkoxy silane containing an amine group, or an ion exchange resin.

Based on a total amount of 100 g of the silane monomer and/or the polysiloxane, the range of the usage amount of the catalyst is preferably 0.005 g to 15 g; more preferably 0.01 g to 12 g; and even more preferably 0.05 g to 10 g.

Concerning stability, the polysiloxane polymer (B) obtained through a condensation reaction preferably does not contain a byproduct (such as alcohol or water) and a catalyst. Therefore, the polysiloxane (B) obtained can be optionally purified. The purification method is not particularly limited. Preferably, a hydrophobic solvent is used to dilute the polysiloxane polymer (B). Then, alcohol or water is removed through an organic layer washed with water several times and concentrated by an evaporator. Moreover, an ion exchange resin can be used to remove the catalyst.

Based on 100 parts by weight of the alkali-soluble resin (A), the usage amount of the polysiloxane polymer (B) is 10 parts by weight˜100 parts by weight, preferably 12 parts by weight˜90 parts by weight, and more preferably 15 parts by weight˜80 parts by weight.

### Compound (C) Containing an Ethylenically Unsaturated Group

The compound (C) containing an ethylenically unsaturated group of the invention includes at least one compound selected from the group consisting of the compound represented by formula (6) and the compound represented by formula (7), or other compounds containing an ethylenically unsaturated group.

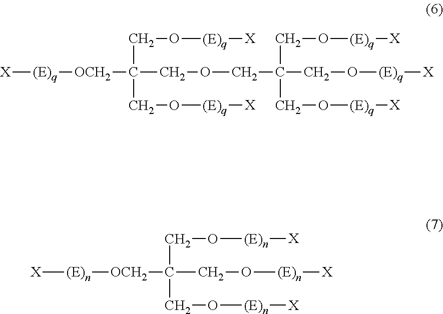

In formula (6) and formula (7), each E independently represents —((CH₂)_{y}CH₂O)— or —((CH₂)_{y}CH(CH₃)O)—. In particular, each y independently represents an integer of 1˜10; and each X independently represents an acryloyl group, a methacryloyl group, a hydrogen atom, or a carboxyl group. In formula (6), the total number of the acryloyl groups and the methacryloyl groups represented by X is 5 or 6, each q independently represents an integer of 0˜10, and the sum of each q is an integer of 1˜60. In formula (7), the total number of the acryloyl groups and the methacryloyl groups represented by X is 3 or 4, each n independently represents an integer of 0˜10, and the sum of each n is an integer of 1˜40.

The compound represented by formula (6) or (7) can be synthesized by the following known steps: a step of bonding pentaerythritol or dipentaerythritol to a ring-opened skeleton of ethylene oxide or propylene oxide by a ring-opening addition reaction; and a step of introducing a (meth)acryloyl group to the terminal hydroxyl group of the ring-opened skeleton by, for instance, reacting with (meth)acryloyl chloride. Each step is commonly known, and those having ordinary skill in the art can readily synthesize the compound represented by formula (6) or (7).

In the compounds represented by formula (6) and (7), a pentaerythritol derivative and/or a dipentaerythritol derivative are preferred.

Specific examples of the compound represented by formula (6) are compounds represented by formula (6-1) to formula (6-4), and formula (6-1) and formula (6-2) are preferred. In particular, the sum of each n in formula (6-1) and formula (6-4) is 6; and the sum of each n in formula (6-2) and formula (6-3) is 12. The compound represented by formula (6) can also be a commercial product such as KAYARAD DPEA-12 (manufactured by Nippon Kayaku Co., Ltd.)

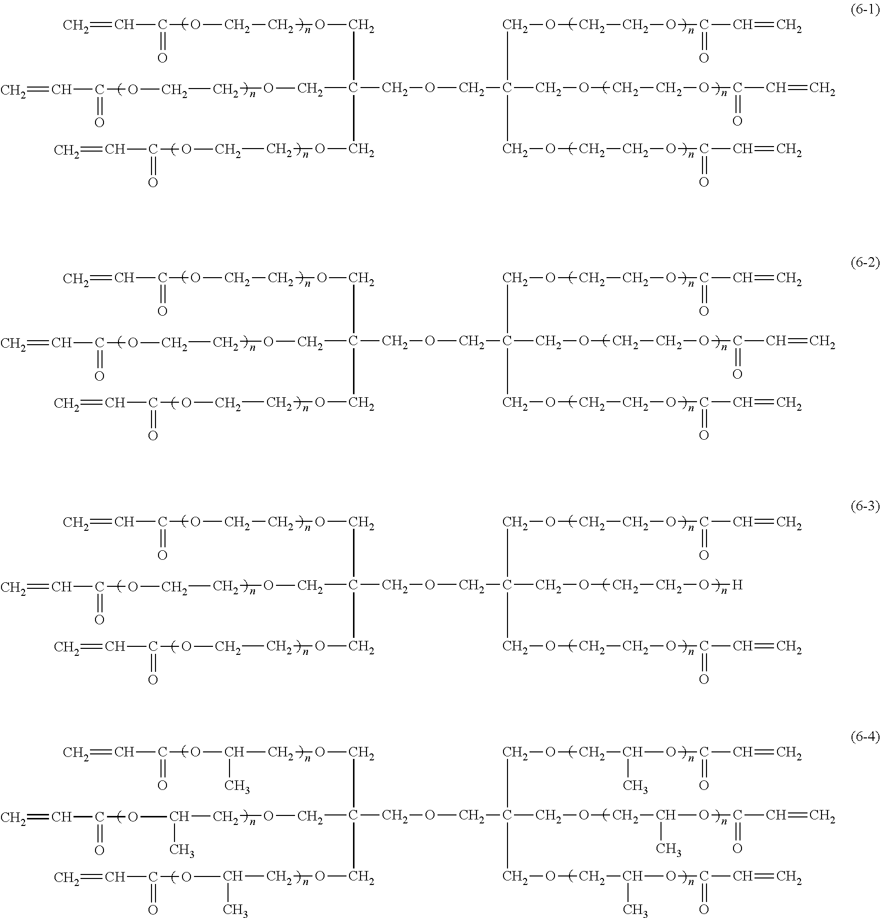

Specific examples of the compound represented by formula (7) are compounds represented by formula (7-1) and formula (7-2), ethoxylated pentaerythritol tetraacrylate, and propoxylated pentaerythritol tetraacrylate. In particular, the sum of each m in formula (7-1) is 4; and the sum of each m in formula (7-2) is 12. The compound represented by formula (7) can also be a commercial product such as EM2411 or EM2421 (manufactured by Eternal Chemical Co., Ltd.); or Miramer M4004 (manufactured by Toyo Chemical Co., Ltd.)

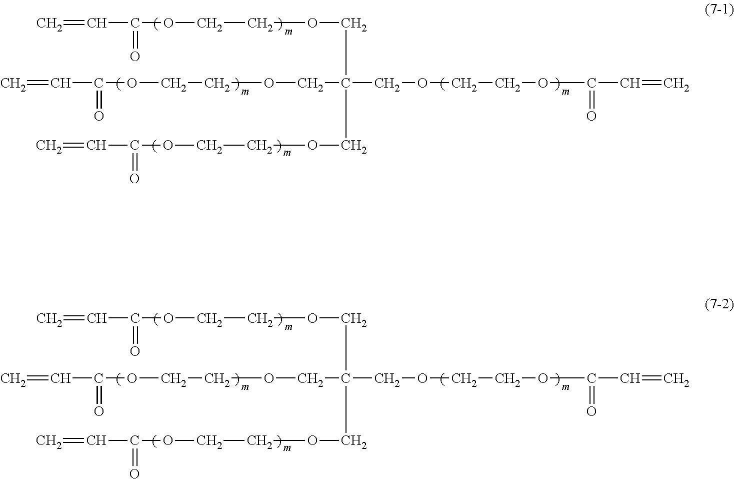

Other compounds containing an ethylenically unsaturated group include a compound selected from the group consisting of (meth)acrylate compound obtained by reacting caprolactone-modified polyalcohol and (meth)acrylic acid and a compound having the functional group represented by formula (8).

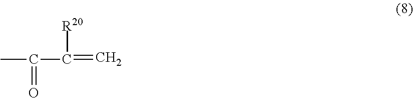

In formula (8), R²⁰ represents a hydrogen atom or a methyl group.

The caprolactone-modified polyalcohol is manufactured by reacting carpolactone and polyalcohol with four or more functional groups. In particular, the carpolactone can be γ-carpolactone, δ-carpolactone, or ε-carpolactone, preferably ε-carpolactone. The polyalcohol with four or more functional groups can be pentaerythritol, di(trimethylolpropane), or dipentaerythritol.

Specific examples of the (meth)acrylate compound can include: a pentaerythritol caprolactone-modified tetra(meth)acrylate compound, a di(trimethylolpropane) caprolactone-modified tetra(meth)acrylate compound, and a dipentaerythritol caprolactone-modified poly(meth)acrylate compound. In particular, specific examples of the dipentaerythritol caprolactone-modified poly(meth)acrylate compound include: a dipentaerythritol caprolactone-modified di(meth)acrylate compound, a dipentaerythritol caprolactone-modified tri(meth)acrylate compound, a dipentaerythritol caprolactone-modified tetra(meth)acrylate compound, a dipentaerythritol caprolactone-modified penta(meth)acrylate compound, and a dipentaerythritol caprolactone-modified hexa(meth)acrylate compound.

More specifically, the structure of the dipentaerythritol caprolactone-modified poly(meth)acrylate can be represented by formula (9):

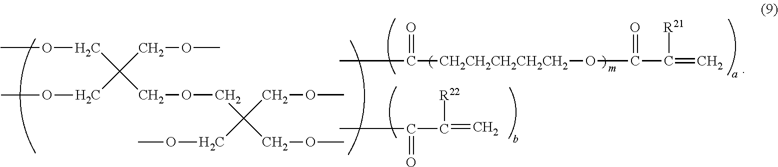

In formula (9), R²¹ and R²² respectively represent a hydrogen atom or a methyl group; m is an integer of 1-2; a is an integer of 1-6; and b is an integer of 0-5. In particular, a+b=2-6, preferably a+b=3-6, more preferably a+b=5-6, and most preferably a+b=6.

More specifically, the (meth)acrylate compound is a product manufactured by Nippon Kayaku Co., Ltd., Japan, and examples thereof include, for instance, KAYARAD®DPCA-20, DPCA-30, DPCA-60, and DPCA-120.

Specific examples of the compound having the functional group represented by formula (8) can include: acrylamide, (meth)acryloylmorpholine, 7-amino-3,7-dimethyloctyl(meth)acrylate, iso-butoxymethyl(meth)acrylamide, iso-bornyloxyethyl(meth)acrylate, iso-bornyl(meth)acrylate, 2-ethylhexyl(meth)acrylate, ethyl diethylene glycol(meth)acrylate, t-octyl(meth)acrylamide, diacetone(meth)acrylamide, dimethylamino(meth)acrylate, dodecyl(meth)acrylate, dicyclopentenyloxyethyl(meth)acrylate, dicyclopentenyl(meth)acrylate, N,N-dimethyl(meth)acrylamide, tetrachlorophenyl(meth)acrylate, 2-tetrachlorophenoxy ethyl(meth)acrylate, tetrahydrofurfuryl(meth)acrylate, tetrabromophenyl(meth)acrylate, 2-tetrabromophenoxyethyl(meth)acrylate, 2-trichlorophenoxyethyl(meth)acrylate, tribromophenyl(meth)acrylate, 2-tribromophenoxyethyl(meth)acrylate, 2-hydroxyethyl(meth)acrylate, 2-hydroxypropyl(meth)acrylate, vinylcaprolactam, N-vinylpyrrolidone, phenoxyethyl(meth)acrylate, pentachlorophenyl(meth)acrylate, pentabromophenyl(meth)acrylate, polyethylene glycol mono(meth)acrylate, polypropylene glycol mono(meth)acrylate, bornyl(meth)acrylate, ethylene glycol di(meth)acrylate, dicyclopentenyldi(meth)acrylate, triethylene glycol di(meth)acrylate, tetraethylene glycol di(meth)acrylate, tri(2-hydroxyethyl) isocyanurate di(meth)acrylate, tri(2-hydroxyethyl) isocyanurate tri(meth)acrylate, caprolactone-modified tri(2-hydroxyethyl) isocyanurate tri(meth)acrylate, trimethylolpropyl tri(meth)acrylate, triethylene glycol di(meth)acrylate, neo-pentylene glycol di(meth)acrylate, 1,4-butanediol di(meth)acrylate, 1,6-hexanediol di(meth)acrylate, pentaerythritol tri(meth)acrylate, pentaerythritol tetra(meth)acrylate, polyester di(meth)acrylate, polyethylene glycol di(meth)acrylate, dipentaerythritol hexa(meth)acrylate, dipentaerythritol penta(meth)acrylate, dipentaerythritol tetra(meth)acrylate, ditrimethylolpropyl tetra(meth)acrylate, EO-modified bisphenol A di(meth)acrylate, PO-modified bisphenol A di(meth)acrylate, EO-modified hydrogenated bisphenol A di(meth)acrylate, PO-modified hydrogenated bisphenol A di(meth)acrylate, EO-modified bisphenol F di(meth)acrylate, and phenolic polyglycidyl ether(meth)acrylate.

The compound having the functional group represented by formula (8) is preferably selected from the group consisting of trimethylolpropyl triacrylate, pentaerythritol triacrylate, pentaerythritol tetraacrylate, dipentaerythritol hexaacrylate, dipentaerythritol pentaacrylate, dipentaerythritol tetraacrylate, ditrimethylolpropyl tetraacrylate, TO-1382 manufactured by Toagosei Co, Ltd., Japan, and the composition thereof.

Based on 100 parts by weight of the alkali-soluble resin (A), the usage amount of the compound (C) containing an ethylenically unsaturated group is 40 parts by weight˜400 parts by weight, preferably 80 parts by weight˜350 parts by weight, and more preferably 100 parts by weight˜300 parts by weight.

### Photoinitiator (D)

The photoinitiator (D) of the invention is at least one compound selected from the group consisting of an acetophenone compound, a biimidazole compound, and an acyl oxime compound.

Specific examples of the acetophenone compound include: p-dimethylamino-acetophenone, α,α′-dimethoxyazoxy-acetophenone, 2,2′-dimethyl-2-phenyl-acetophenone, p-methoxy-acetophenone, 2-methyl-1-(4-methylthio phenyl)-2-morpholino-1-propanone, and 2-benzyl-2-N,N-dimethylamino-1-(4-morpholinophenyl)-1-butanone.

Specific examples of the biimidazole compound include: 2,2′-bis(o-chlorophenyl)-4,4′,5,5′-tetraphenyl-biimidazole, 2,T-bis(o-fluorophenyl)-4,4′,5,5′-tetraphenyl-biimidazole, 2,T-bis(o-methyl phenyl)-4,4′,5,5′-tetraphenyl-biimidazole, 2,2′-bis(o-methoxyphenyl)-4,4′,5,5′-tetraphenyl-biimidazole, 2,2′-bis(o-ethylphenyl)-4,4′,5,5′-tetraphenyl-biimidazole, 2,2′-bis(p-methoxyphenyl)-4,4′,5,5′-tetraphenyl-biimidazole, 2,2′-bis(2,2′,4,4′-tetramethoxyphenyl)-4,4′,5,5′-tetraphenyl-biimidazole, 2,2′-bis(2-chlorophenyl)-4,4′,5,5′-tetraphenyl-biimidazole, and 2,T-bis(2,4-dichlorophenyl)-4,4′,5,5′-tetraphenyl-biimidazole.

Specific examples of the acyl oxime compound include: ethanone,1-[9-ethyl-6-(2-methylbenzoyl)-9H-carbazole-3-yl]-,1-(0-acetyl oxime) such as CGI-242 manufactured by Ciba Specialty Chemicals having the structure represented by formula (10), 1-(4-phenyl-thio-phenyl)-octane-1,2-dion 2-oxime-O-benzoate such as CGI-124 manufactured by Ciba Specialty Chemicals having the structure represented by formula (11), and ethanone,1-[9-ethyl-6-(2-chloro-4-benzyl-thio-benzoyl)-9H-carbazole-3-yl]-,1-(O-acetyl oxime) manufactured by Asahi Denka Co., Ltd. having the structure represented by formula (12).

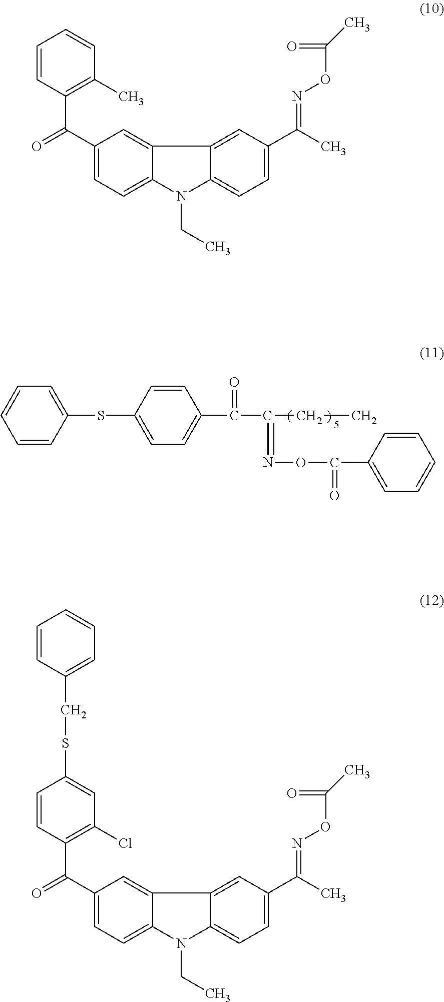

The photoinitiator (D) is preferably 2-methyl-1-(4-methylthio phenyl)-2-morpholino-1-propanone, 2-benzyl-2-N,N-dimethylamino-1-(4-morpholinophenyl)-1-butanone, 2,2′-bis(O-chlorophenyl)-4,4′,5,5′-tetraphenylbiimidazole, ethanone,1-[9-ethyl-6-(2-methylbenzoyl)-9H-carbazole-3-yl]-,1-(0-acetyl oxime), or combinations of the compounds.

The photoinitiator (D) can optionally further include the following compounds as needed: benzophenone compounds such as thioxanthone, 2,4-diethyl-thioxanthanone, thioxanthone-4-sulfone, benzophenone, 4,4′-bis(dimethylamino)benzophenone, and c4,4′-bis(diethylamino)benzophenone; an α-diketone compound such as benzyl; an acyloin compound such as benzoin; acyloin ether compounds such as benzoin methylether, benzoin ethylether, and benzoin isopropyl ether; acylphosphineoxide compounds such as 2,4,6-trimethyl-benzoyl-diphenyl-phosphineoxide and bis-(2,6-dimethoxy-benzoyl)-2,4,4-trimethyl-benzyl-phosphineoxide; quinone compounds such as anthraquinone and 1,4-naphthoquinone; halides such as phenacyl chloride, tribromomethyl-phenylsulfone, and tris(trichloromethyl)-s-triazine; and a peroxide such as di-tertbutylperoxide. In particular, the benzophenone compound is preferred, and 4,4′-bis(diethylamino)benzophenone is most preferred.

Based on 100 parts by weight of the alkali-soluble resin (A), the usage amount of the photoinitiator (D) is 10 parts by weight˜100 parts by weight, preferably 12 parts by weight˜80 parts by weight, and more preferably 15 parts by weight˜60 parts by weight.

### Organic Solvent (E)

The organic solvent (E) of the invention needs to be able to dissolve the alkai-soluble resin (A), the polysiloxane polymer (B), the compound (C) containing an ethylenically unsaturated group, and the photoinitiator (D). Moreover, the organic solvent (E) does not react with these components and has appropriate volatility.

Specific examples of the organic solvent (E) can include: (poly)alkylene glycol monoalkyl ethers such as ethylene glycol monomethyl ether, ethylene glycol monoethyl ether, diethylene glycol monomethyl ether, diethylene glycol monoethyl ether, diethylene glycol n-propyl ether, diethylene glycol n-butyl ether, triethylene glycol monomethyl ether, triethylene glycol monoethyl ether, propylene glycol monomethyl ether, propylene glycol monoethyl ether (PGEE), dipropylene glycol monomethyl ether, dipropylene glycol monoethyl ether, dipropylene glycol n-propyl ether, dipropylene glycol n-butyl ether, tripropylene glycol monoethyl ether, and tripropylene glycol monoethyl ether; (poly)alkylene glycol monoalkyl ether acetates such as ethylene glycol monomethyl ether acetate, ethylene glycol monoethyl ether acetate, propylene glycol monomethyl ether acetate, and propylene glycol monoethyl ether acetate; other ethers such as diethylene glycol dimethyl ether, diethylene glycol methyl ethyl ether, diethylene glycol diethyl ether, and tetrahydrofuran; ketones such as methyl ethyl ketone, cyclohexanone, 2-heptanone, 3-heptanone, and diacetone alcohol (DAA); alkyl lactates such as methyl 2-hydroxypropanoate and ethyl 2-hydroxypropanoate; other esters such as methyl 2-hydroxy-2-methylpropanoate, ethyl 2-hydroxy-2-methylpropanoate, methyl 3-methoxypropanoate, ethyl 3-methoxypropanoate, methyl 3-ethoxypropanoate, ethyl 3-ethoxypropanoate (EEP), ethyl ethoxyacetate, ethyl hydroxyacetate, methyl 2-hydroxy-3-methylenebutyrate, 3-methyl-3-methoxybutyl acetate, 3-methyl-3-methoxybutyl propanoate, ethyl acetate, n-propyl acetate, isopropyl acetate, n-butyl acetate, isobutyl acetate, n-amyl acetate, isoamyl acetate, n-butyl propionate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, and ethyl 2-oxybutyrate; aromatic hydrocarbons such as toluene and xylene; and carboxylic amides such as N-methylpyrrolidone, N,N-dimethylformamide, and N,N-dimethylacetamide. The organic solvent (E) is preferably propylene glycol monomethyl ether acetate or ethyl 3-ethoxypropionate. Moreover, the organic solvent (E) can be used alone or in multiple combinations of a plurality of the aforementioned compounds.

Based on 100 parts by weight of the alkali-soluble resin (A), the usage amount of the organic solvent (E) is 500 parts by weight˜5000 parts by weight, preferably 800 parts by weight˜4000 parts by weight, and more preferably 1000 parts by weight˜3000 parts by weight.

### Colorant (F)

The photosensitive resin composition of the invention can further include a colorant (F). The colorant (F) is at least one selected from the group consisting of an inorganic pigment and an organic pigment.

The inorganic pigment includes metal compounds such as metal oxide and metallic complex salt. Examples of the inorganic pigment include the metal oxides such as oxides of iron, cobalt, aluminum, cadmium, lead, copper, titanium, magnesium, chromium, zinc, antimony, and composite oxides of the aforementioned metals.

Examples of the organic pigment include, for instance, C.I. pigment yellow 1, 3, 11, 12, 13, 14, 15, 16, 17, 20, 24, 31, 53, 55, 60, 61, 65, 71, 73, 74, 81, 83, 93, 95, 97, 98, 99, 100, 101, 104, 106, 108, 109, 110, 113, 114, 116, 117, 119, 120, 126, 127, 128, 129, 138, 139, 150, 151, 152, 153, 154, 155, 156, 166, 167, 168, 175; C.I. pigment orange 1, 5, 13, 14, 16, 17, 24, 34, 36, 38, 40, 43, 46, 49, 51, 61, 63, 64, 71, 73; C.I. pigment red 1, 2, 3, 4, 5, 6, 7, 8, 9, 10, 11, 12, 14, 15, 16, 17, 18, 19, 21, 22, 23, 30, 31, 32, 37, 38, 40, 41, 42, 48:1, 48:2, 48:3, 48:4, 49:1, 49:2, 50:1, 52:1, 53:1, 57, 57:1, 57:2, 58:2, 58:4, 60:1, 63:1, 63:2, 64:1, 81:1, 83, 88, 90:1, 97, 101, 102, 104, 105, 106, 108, 112, 113, 114, 122, 123, 144, 146, 149, 150, 151, 155, 166, 168, 170, 171, 172, 174, 175, 176, 177, 178, 179, 180, 185, 187, 188, 190, 193, 194, 202, 206, 207, 208, 209, 215, 216, 220, 224, 226, 242, 243, 245, 254, 255, 264, 265; C.I. pigment violet 1, 19, 23, 29, 32, 36, 38, 39; C.I. pigment blue 1, 2, 15, 15:3, 15:4, 15:6, 16, 22, 60, 66; C.I. pigment green 7, 36, 37; C.I. pigment brown 23, 25, 28; and C.I. pigment black 1, 7.

Based on 100 parts by weight of the alkali-soluble resin (A), the usage amount of the colorant (F) is 20 parts by weight˜150 parts by weight, preferably 25 parts by weight˜120 parts by weight, and more preferably 30 parts by weight˜100 parts by weight.

### Additive (G)

The photosensitive resin composition of the invention can also further contain an additive (G). The additive (G) includes, for instance, a surfactant, a filler, a polymer compound (other than the alkali-soluble resin (A)), an adhesion promoting agent, an antioxidant, an ultraviolet absorber, or an anti-coagulant.

The surfactant can improve the coating property of the photosensitive resin composition of the invention, and examples thereof can include: polyethylene oxide alkyl ethers such as polyethylene oxide lauryl ether, polyethylene oxide stearyl ether, and polyethylene oxide oleyl ether; polyethylene oxide alkyl phenyl ethers such as polyethylene oxide octyl phenyl ether and polyethylene oxide nonyl phenyl ether; polyethylene glycol dialkyl esters such as polyethylene glycol dilaurate and polyethylene glycol distearate; sorbitan fatty acid esters; fatty acid modified polyesters; tertiary amine modified polyurethanes; and KP products manufactured by Shin-Etsu Chemical Co., Ltd., SF-8427 products manufactured by Toray Dow Corning Silicon, Polyflow products manufactured by Kyoei-Sha Yushi Kagaku Kogyo Co., Ltd., F-Top products manufactured by Tochem Products Co., Ltd., Megafac products manufactured by Dainippon Ink & Chemicals, Inc., Fluorade products manufactured by Sumitomo 3M Co., Ltd., Asahi Guard products manufactured by Asahi Glass Co., Ltd., and Surflon products manufactured by Asahi Glass Co., Ltd.

Examples of the filler can include, for instance, glass and aluminum. Examples of the polymer compound can include, for instance: polyvinyl alcohol, polyethylene glycol monoalkyl ether, and polyfluoro alkyl acrylate. Examples of the adhesion promoting agent can include, for instance: vinyltrimethoxysilane, vinyltriethoxysilane, vinyltris(2-methoxyethoxy)silane, N-(2-aminoethyl)-3-aminopropylmethyldimethoxysilane, N-(2-aminoethyl)-3-aminopropyltrimethoxysilane, 3-aminopropyltriethoxysilane, 3-glycidyloxy propyltrimethoxysilane, 3-glycidyloxy propylmethyldimethoxysilane, 2-(3,4-epoxycyclohexyl)ethyltrimethoxysilane, 3-chloropropylmethyl dimethoxysilane, 3-chloropropyltrimethoxysilane, 3-methacryloyloxypropyltrimethoxysilane, and 3-mercaptopropyltrimethoxysilane. Examples of the antioxidant can include, for instance: 2,2-thiobis(4-methyl-6-t-butylphenol) and 2,6-di-t-butylphenol. Examples of the ultraviolet absorber can include, for instance: 2-(3-t-butyl-5-methyl-2-hydroxyphenyl)-5-chlorophenylazide and alkoxyphenone. Examples of the anti-coagulant can include, for instance: sodium polyacrylate.

Based on a usage amount of 100 parts by weight of the alkali-soluble resin (A), the usage amount of the additive (G) is 1 part by weight˜10 parts by weight, preferably 1.5 parts by weight˜8 parts by weight, and more preferably 2 parts by weight˜6 parts by weight.

The invention also provides a method for manufacturing a color filter. The method for manufacturing a color filter of the invention is described in detail below.

### <Preparation of Photosensitive Resin Composition>

The alkali-soluble resin (A), the polysiloxane polymer (B), the compound (C) containing an ethylenically unsaturated group, the photoinitiator (D), and the organic solvent (E) are placed and stirred in a mixer such that the components are uniformly mixed into a solution state, and if needed, the colorant (F) or the additive (G) can also be added. After the components are uniformly mixed, the photosensitive resin composition in the solution state can be prepared.

The method for preparing the transparent photosensitive resin composition is not particularly limited. For instance, a portion of the alkali-soluble resin (A) and a portion of the compound (C) containing an ethylenically unsaturated group can be first dispersed in a portion of the organic solvent (E) to form a dispersion liquid, and then the rest of the alkali-soluble resin (A), the polysiloxane polymer (B), the compound (C) containing an ethylenically unsaturated group, the photoinitiator (D), and the organic solvent (E) are mixed into the dispersion liquid to obtain the transparent photosensitive resin composition.

The method for preparing the colored photosensitive resin composition is not particularly limited. For instance, the colorant (F) can be directly added and dispersed in the photosensitive resin composition for a color filter; alternatively, a portion of the colorant (F) can first be dispersed in a portion of the alkali-soluble resin (A) and a portion of the organic solvent (E) to form a colorant dispersion liquid, and then the rest of the alkali-soluble resin (A), the polysiloxane polymer (B), the compound (C) containing an ethylenically unsaturated group, the photoinitiator (D), and the organic solvent (E) are mixed into the colorant dispersion liquid. The process of dispersing the colorant (F) can be performed by using a mixer such as a beads mill or a roll mill to mix the components.

### <Formation of Pixel Layer>

The photosensitive resin composition solution in the solution sate can be coated on a substrate by, for instance, spin coating, cast coating, or roll coating. The substrate can be, for instance, a glass for a liquid crystal display apparatus such as alkali-free glass, soda-lime glass, hard glass (Pyrex glass), quartz glass, or those glass with a transparent conductive film attached thereto; a substrate (such as a silicon substrate) for a photoelectric conversion apparatus (such as a solid-state imaging device); or a substrate on which a black matrix for shielding light capable of isolating the pixel colored layer such as red, green, and blue pixels.

After the photosensitive resin composition is coated, most of the organic solvent contained in the photosensitive resin composition is first removed by a drying process under reduced pressure, and then the remaining organic solvent is completely removed by a pre-bake process to form a pre-baked coating film. During the process, the operating conditions of the drying process under reduced pressure and the pre-bake process vary according to the kinds and the mixing ratio of each component. Generally, the drying process under reduced pressure is performed at a pressure of 0 mmHg to 200 mmHg for 1 second to 60 seconds, and the pre-bake process is performed at a temperature of 70° C. to 110° C. for 1 minute to 15 minutes.

After the pre-bake process, an exposure process is performed on the pre-baked coating film using a photomask with a predetermined pattern. The light used in the exposure process is preferably an ultraviolet (UV) ray such as a g-ray, a h-ray, or an i-ray, and the equipment for emitting the UV ray is, for instance, a(n) (ultra-)high pressure mercury lamp or a metal halide lamp.

After the exposure process, the pre-baked coating film is immersed in a developing solution at a temperature of 23±2° C. and developed for about 15 seconds to 5 minutes to remove the unnecessary portion of the pre-baked coating film so as to form a predetermined pattern on the substrate. The developing solution can be an alkali aqueous solution containing alkali compounds such as sodium hydroxide, potassium hydroxide, sodium carbonate, sodium bicarbonate, potassium carbonate, potassium bicarbonate, sodium silicate, sodium methylsilicate, aqueous ammonia, ethylamine, diethylamine, dimethyl ethanol amine, tetramethylammonium hydroxide, tetraethylammonium hydroxide, choline, pyrrole, piperidine, or 1,8-diazabicyclo-[5,4,0]-7-undecene. The concentration thereof is 0.001 wt %-10 wt %, preferably 0.005 wt %-5 wt %, and more preferably 0.01 wt %-1 wt %.

Next, the pattern on the substrate is washed with water, and then the pattern is dried with compressed air or compressed nitrogen. Lastly, a post-bake process is performed on the pattern with a heating apparatus such as a hot plate or an oven. In particular, the heating temperature is set between 150° C. and 250° C., the heating time when using the hot plate is 5 minutes to 60 minutes, and the heating time when using the oven is 15 minutes to 150 minutes. The pattern is thereby fixed so as to form a pixel layer. By repeating the steps, pixel layers of, for instance, red, green, and blue can be formed in sequence on the substrate.

### <Formation of Protective Film>

The method for forming the protective film of the invention includes coating the transparent photosensitive resin composition on the substrate on which pixel layers of, for instance, red, green, and blue are formed, and then performing a heating process such as a pre-bake process to remove the solvent therein, so that the protective film is formed.

The coating method can be, for instance, spray coating, roller coating, spin coating, bar coating, or ink jet coating. The coating method is preferably performed with a spin coater, a spin-less coating machine, or a slit-die coating machine.

Conditions of the pre-bake process vary according to the kinds and the mixing ratio of each component. Generally, the pre-bake process is performed at a temperature of 70° C. to 90° C. for 1 minute to 15 minutes. After the pre-bake process, the thickness of the pre-baked coating film formed is 0.15 μm to 8.5 preferably 0.15 μm to 6.5 μm, and more preferably 0.15 μm to 4.5 μm. It should be understood that the thickness of the pre-baked coating film refers to the thickness after the solvent is removed.

After the pre-baked coating film is formed, a heating process is performed with a heating apparatus such as a hot plate or an oven. The temperature of the heat treatment is generally 150° C. to 250° C., the heating time when using the hot plate is 5 minutes to 30 minutes; and the heating time when using the oven is 30 minutes to 90 minutes.

When the transparent photosensitive resin composition contains the photoinitiator, if needed, an exposure treatment can be performed on the pre-baked coating film after the transparent photosensitive resin composition is coated on the surface of the substrate and the solvent is removed with a pre-bake process to form the pre-baked coating film.

The light used in the exposure process can be, for instance, visible light, UV ray, far-UV ray, electron beam, or x-ray. In addition, UV ray with a wavelength of 190 nm to 450 nm is preferred.

The exposure quantity of the exposure treatment is preferably 100 J/m² to 20,000 J/m², but more preferably 150 J/m² to 10,000 J/m².

After the exposure treatment, a heat treatment can optionally be performed with a heating apparatus such as a hot plate or an oven. The temperature of the heat treatment is generally 150° C. to 250t, the heating time when using the hot plate is 5 minutes to 30 minutes; and the heating time when using the oven is 30 minutes to 90 minutes.

### <Formation of Color Filter>

After forming the pixel layers of for instance, red, green, the blue and the protective film, a sputtering process is performed on the surface of the protective film in a vacuum environment at a temperature of 220° C. to 250° C. to form an ITO protective film. If needed, an etching process and a wiring process can be performed on the ITO protective film. Then, an alignment film can be coated on the surface of the ITO protective film. A color filter containing a cured product formed by curing the photosensitive resin composition of the invention is thus manufactured. The alignment film is not particularly limited, and any known alignment film can be used.

The invention further provides a liquid crystal display apparatus. The manufacturing method thereof is as follows.

### <Manufacture of Liquid Crystal Display Apparatus>

The substrate with the color filter formed by the method for manufacturing the color filter and a driving substrate provided with a thin film transistor (TFT) are arranged opposite to each other with a cell gap in between. A sealing agent is used to adhere the peripheral portion of the two substrates, leaving an injection hole, and liquid crystals are filled into the cell gap defined by the surfaces of the substrates and the sealing agent through the injection hole. Lastly, the injection hole is sealed up to form a liquid crystal cell. Then, a polarizer is adhered to the outer surface of the liquid crystal cell (i.e., the surfaces of each substrate opposite to the liquid crystal side) to manufacture the liquid crystal display apparatus. The liquid crystal is not particularly limited, and any known liquid crystal can be used.

Embodiments are provided as examples to describe the invention in detail, but the invention is not limited to the contents disclosed in the embodiments.

### Preparation Embodiments

### Preparation of Component (a-1)

### Preparation Embodiment (a-1-1)

100 parts by weight of a fluorene epoxy compound (ESF-300 manufactured by Nippon Steel Chemical; epoxy equivalent of 231), 30 parts by weight of acrylic acid, 0.3 parts by weight of benzyltriethylammonium chloride, 0.1 parts by weight of 2,6-di-t-butyl-p-cresol, and 130 parts by weight of propylene glycol monomethyl ether acetate were added continuously to a 500 mL 4-neck flask. The feed rate was controlled at 25 parts by weight/minute. In particular, the temperature of the reaction process was maintained at 100° C.-110° C. and the reaction lasted 15 hours. A yellowish transparent mixture having a solid component content of 50 wt % was thus obtained. Then, steps such as extraction, filtration, and heating and drying were performed to obtain a diol compound (a-1-1) containing a polymeric unsaturated group and having a solid component content of 99.9 wt %.

### Preparation Embodiment (a-1-2)

100 parts by weight of a fluorene epoxy compound (PG-100 manufactured by Osaka Gas; epoxy equivalent of 259), 35 parts by weight of methacrylic acid, 0.3 parts by weight of benzyltriethylammonium chloride, 0.1 parts by weight of 2,6-di-t-butyl-p-cresol, and 135 parts by weight of propylene glycol monomethyl ether acetate were added continuously to a 500 mL 4-neck flask. The feed rate was controlled at 25 parts by weight/minute. In particular, the temperature of the reaction process was maintained at 100° C.˜110° C. and the reaction lasted 15 hours. A yellowish transparent mixture having a solid component content of 50 wt % was thus obtained. Then, steps such as extraction, filtration, and heating and drying were performed to obtain a diol compound (a-1-2) containing a polymeric unsaturated group and having a solid component content of 99.9 wt %.

### Preparation Embodiment (a-1-3)

100 parts by weight of a fluorene epoxy compound (ESF-300 manufactured by Nippon Steel Chemical; epoxy equivalent of 231), 100 parts by weight of 2-methacryloylethoxy succinate, 0.3 parts by weight of benzyltriethylammonium chloride, 0.1 parts by weight of 2,6-di-t-butyl-p-cresol, and 200 parts by weight of propylene glycol monomethyl ether acetate were added continuously to a 500 mL 4-neck flask. The feed rate was controlled at 25 parts by weight/minute. In particular, the temperature of the reaction process was maintained at 100° C.˜110° C. and the reaction lasted 15 hours. A yellowish transparent mixture having a solid component content of 50 wt % was thus obtained. Then, steps such as extraction, filtration, and heating and drying were performed to obtain a diol compound (a-1-3) containing a polymeric unsaturated group and having a solid component content of 99.9 wt %.

### Preparation Embodiment (a-1-4)

0.3 mol of bis(4-hydroxyphenyl)sulfone, 9 mol of 3-chlroro-1,2-epoxypropane, and 0.003 mol of tetramethyl ammonium chloride were added to a 1000 mL 3-neck flask equipped with a mechanical agitator, a thermometer, and a reflux condenser. The mixture was heated to 105° C. while stirring and reacted for 9 hours. The unreacted 3-chlroro-1,2-epoxypropane was distilled off under reduced pressure. The reaction system was cooled to room temperature, and a 30 wt % aqueous solution formed by dissolving 9 mol of benzene and 0.5 mol of sodium hydroxide in water was added while stirring, and then the reaction system was heated to 60° C. and kept at 60° C. for 3 hours. Next, the reaction solution was repeatedly washed with water until no Cl⁻ remained (tested with AgNO₃). Lastly, the solvent benzene was distilled off under reduced pressure and dried at 75° C. for 24 hours to obtain an epoxy compound of bis(4-hydroxyphenyl)sulfone.

100 parts by weight of the epoxy compound of bis(4-hydroxyphenyl)sulfone (epoxy equivalent of 181), 30 parts by weight of acrylic acid, 0.3 parts by weight of benzyltriethylammonium chloride, 0.1 parts by weight of 2,6-di-t-butyl-p-cresol, and 130 parts by weight of propylene glycol monomethyl ether acetate were added continuously to a 500 mL 4-neck flask. The feed rate was controlled at 25 parts by weight/minute. In particular, the temperature of the reaction process was maintained at 100° C.-110° C. and the reaction lasted 15 hours. A yellowish transparent mixture having a solid component content of 50 wt % was thus obtained. Then, steps such as extraction, filtration, and heating and drying were performed to obtain a diol compound (a-1-4) containing a polymeric unsaturated group and having a solid component content of 99.9 wt %.

### Preparation Embodiment (a-1-5)

0.3 mol of bis(4-hydroxyphenyl)hexafluoropropane, 9 mol of 3-chlroro-1,2-epoxypropane, and 0.003 mol of tetramethyl ammonium chloride were added to a 1000 mL 3-neck flask equipped with a mechanical agitator, a thermometer, and a reflux condenser. The mixture was heated to 105° C. while stirring and reacted for 9 hours. The unreacted 3-chlroro-1,2-epoxypropane was distilled off under reduced pressure. The reaction system was cooled to room temperature, and a 30 wt % aqueous solution formed by dissolving 9 mol of benzene and 0.5 mol of sodium hydroxide in water was added while stirring, and then the reaction system was heated to 60° C. and kept at 60° C. for 3 hours. Next, the reaction solution was repeatedly washed with water until no Cl⁻ remained (tested with AgNO₃). Lastly, the solvent benzene was distilled off under reduced pressure and dried at 75° C. for 24 hours to obtain an epoxy compound of bis(4-hydroxyphenyl)hexafluoropropane.

100 parts by weight of the epoxy compound of bis(4-hydroxyphenyl)hexafluoropropane (epoxy equivalent of 224), 35 parts by weight of methacrylic acid, 0.3 parts by weight of benzyltriethylammonium chloride, 0.1 parts by weight of 2,6-di-t-butyl-p-cresol, and 135 parts by weight of propylene glycol monomethyl ether acetate were added continuously to a 500 mL 4-neck flask. The feed rate was controlled at 25 parts by weight/minute. In particular, the temperature of the reaction process was maintained at 100° C.-110° C. and the reaction lasted 15 hours. A yellowish transparent mixture having a solid component content of 50 wt % was thus obtained. Then, steps such as extraction, filtration, and heating and drying were performed to obtain a diol compound (a-1-5) containing a polymeric unsaturated group and having a solid component content of 99.9 wt %.

### Preparation Embodiment (a-1-6)

0.3 mol of bis(4-hydroxyphenyl)dimethylsilane, 9 mol of 3-chlroro-1,2-epoxypropane, and 0.003 mol of tetramethyl ammonium chloride were added to a 1000 mL 3-neck flask equipped with a mechanical agitator, a thermometer, and a reflux condenser. The mixture was heated to 105° C. while stirring and reacted for 9 hours. The unreacted 3-chlroro-1,2-epoxypropane was distilled off under reduced pressure. The reaction system was cooled to room temperature, and a 30 wt % aqueous solution foil led by dissolving 9 mol of benzene and 0.5 mol of sodium hydroxide in water was added while stirring, and then the reaction system was heated to 60° C. and kept at 60° C. for 3 hours. Next, the reaction solution was repeatedly washed with water until no Cl⁻ remained (tested with AgNO₃). Lastly, the solvent benzene was distilled off under reduced pressure and dried at 75° C. for 24 hours to obtain an epoxy compound of bis(4-hydroxyphenyl)dimethylsilane.

100 parts by weight of the epoxy compound of bis(4-hydroxyphenyl)dimethylsilane (epoxy equivalent of 278), 100 parts by weight of 2-methacryloyl oxyethyl succinate monoester, 0.3 parts by weight of benzyltriethylammonium chloride, 0.1 parts by weight of 2,6-di-t-butyl-p-cresol, and 200 parts by weight of propylene glycol monomethyl ether acetate were added continuously to a 500 mL 4-neck flask. The feed rate was controlled at 25 parts by weight/minute. In particular, the temperature of the reaction process was maintained at 100° C.-110° C. and the reaction lasted 15 hours. A yellowish transparent mixture having a solid component content of 50 wt % was thus obtained. Then, steps such as extraction, filtration, and heating and drying were performed to obtain a diol compound (a-1-6) containing a polymeric unsaturated group and having a solid component content of 99.9 wt %.

### Preparation of Alkai-Soluble Resin (A-1)

### Synthesis Embodiment 1

1 mol of the diol compound (a-1-1) containing a polymeric unsaturated group, 1.9 g of benzyltriethylammonium chloride, and 0.6 g of 2,6-di-t-butyl-p-cresol were dissolved in 900 g of ethylene glycol monoethyl ether acetate, while 0.2 mol of 3,3′,4,4′-biphenyltetracarboxylic dianhydride (a-2-1) and 1.6 mol of trimethoxysilylpropyl succinic anhydride (a-3-1) were added. The mixture was heated to 110° C. and reacted for 2 hours (simultaneously addition) to obtain an alkali-soluble resin (hereinafter referred to as A-1-1) having an acid value of 100 mgKOH/g and a number average molecular weight (Mn) of 1566.

### Synthesis Embodiment 2

1 mol of the diol compound (a-1-2) containing a polymeric unsaturated group, 2.0 g of benzyltriethylammonium chloride, and 0.7 g of 2,6-di-t-butyl-p-cresol were dissolved in 900 g of ethylene glycol monoethyl ether acetate, and 0.3 mol of 3,3′,4,4′-benzophenone tetracarboxylic dianhydride (a-2-2) was added. The mixture was reacted at 90° C. for 2 hours, and then 1.4 mol of triethoxysilylpropyl succinic anhydride (a-3-2) was added. Lastly, the mixture was reacted at 90° C. for 4 hours (successively addition) to obtain an alkali-soluble resin (hereinafter referred to as A-1-2) having an acid value of 90 mgKOH/g and a number average molecular weight of 1981.

### Synthesis Embodiments 3-10

In addition to the conditions indicated in Table 1, the alkali-soluble resins (A-1-3)˜(A-1-10) were synthesized using the same methods as synthesis embodiments 1 and 2.

### Preparation of Alkai-Soluble Resin (A-2)

### Comparative Synthesis Embodiment 1

1 mol of the diol compound (a-1-1) containing a polymeric unsaturated group, 1.9 g of benzyltriethylammonium chloride, and 0.6 g of 2,6-di-t-butyl-p-cresol were dissolved in 700 g of ethylene glycol monoethyl ether acetate, while 0.3 mol of 3,3′,4,4′-biphenyltetracarboxylic dianhydride (a-2-1) and 1.4 mol of succinic anhydride (a-4-1) were added. The mixture was heated to 110° C. and reacted for 2 hours to obtain an alkali-soluble resin (hereinafter referred to as A-2-1) having an acid value of 130 mgKOH/g and a number average molecular weight of 1888.

### Comparative Synthesis Embodiments 2-3

In addition to the conditions indicated in Table 2, the alkali-soluble resins (A-2-2)˜(A-2-3) were synthesized using the same method as comparative synthesis embodiment 1.

### Preparation of Polysiloxane Polymer (B)

### Preparation Embodiment B-1

0.30 mol of methyltrimethoxysilane (hereinafter referred to as MTMS), 0.65 mol of phenyltrimethoxysilane (hereinafter referred to as PTMS), 0.05 mol of 3-(triethoxysilyl) propyl succinic anhydride (hereinafter referred to as GF-20), and 200 g of propylene glycol monoethyl ether (hereinafter referred to as PGEE) were added to a 500 mL 3-necked flask, and an aqueous solution of oxalic acid (0.40 g of oxalic acid/75 g of H₂O) was added within 30 minutes while stirring the mixture at room temperature. Then, the flask was immersed in an oil bath at 30° C. and stirred for 30 minutes, and then the temperature of the oil bath was raised to 120° C. within 30 minutes. When the internal temperature of the solution reached 105° C., the mixture was continuously heated and stirred to perform polycondensation for 6 hours. Lastly, the solvent was removed with a distillation method to obtain a polysiloxane polymer (B−1).

The types of raw materials and the usage amount of each thereof of preparation embodiment B-1 are as shown in Table 3.

### Preparation Embodiment B-2

0.40 mol of dimethyl dimethoxy silane (hereinafter referred to as DMDMS), 0.40 mol of PTMS, 0.20 mol of phenyltriethoxysilane (hereinafter referred to as PTES), 100 g of PGEE, and 100 g of diacetone alcohol (hereinafter referred to as DAA) were added to a 500 mL 3-necked flask, and an aqueous solution of oxalic acid (0.40 g of oxalic acid/75 g of H₂O) was added within 30 minutes while stirring the mixture at room temperature. Then, the flask was immersed in an oil bath at 30° C. and stirred for 30 minutes, and then the temperature of the oil bath was raised to 120° C. within 30 minutes. When the internal temperature of the solution reached 110° C., the mixture was continuously heated and stirred to perform polycondensation for 5 hours. Lastly, the solvent was removed with a distillation method to obtain a polysiloxane polymer (B-2). The types of raw materials and the usage amount of each thereof of preparation embodiment B-2 are as shown in Table 3.

### Preparation Embodiment B-3

0.60 mol of DMDMS, 0.35 mol of PTMS, 0.05 mol of 3-(trimethoxysilyl) propyl glutaric anhydride (hereinafter referred to as TMSG), and 200 g of PGEE were added to a 500 mL 3-necked flask, and an aqueous solution of oxalic acid (0.35 g of oxalic acid/75 g of H₂O) was added within 30 minutes while stirring the mixture at room temperature. Then, the flask was immersed in an oil bath at 30° C. and stirred for 30 minutes, and then the temperature of the oil bath was raised to 120° C. within 30 minutes. When the internal temperature of the solution reached 105° C., the mixture was continuously heated and stirred to perform polycondensation for 6 hours, thereby obtaining a polysiloxane polymer (B-3). The types of raw materials and the usage amount of each thereof of preparation embodiment B-3 are as shown in Table 3.

### Preparation Embodiment B-4

0.65 mol of MTMS, 0.25 mol of PTES, 0.09 mol of 3-ethyl-3-[(3-(trimethoxysilyl)propoxy)methyl]oxetane (hereinafter referred to as TMSOX), 0.01 mol of silanol terminal polysiloxane (manufactured by Gelest, Inc., product name “DMS-S27”), and 200 g of PGEE were added to a 500 mL 3-necked flask, and an aqueous solution of oxalic acid (0.45 g of oxalic acid/75 g of H₂O) was added within 30 minutes while stirring the mixture at room temperature. Then, the flask was immersed in an oil bath at 30° C. and stirred for 30 minutes, and then the temperature of the oil bath was raised to 120° C. within 30 minutes. When the internal temperature of the solution reached 110° C., the mixture was continuously heated and stirred to perform polycondensation for 6 hours. Lastly, the solvent was removed with a distillation method to obtain a polysiloxane polymer (B-4). The types of raw materials and the usage amount of each thereof of preparation embodiment B-4 are as shown in Table 3.

### Preparation Embodiment B-5

0.30 mol of DMDMS, 0.62 mol of PTMS, 0.08 mol of 3-ethyl-3-[(3-(triethoxysilyl)propoxy)methyl]oxetane (hereinafter referred to as TESOX), and 200 g of PGEE were added to a 500 mL 3-necked flask, and an aqueous solution of oxalic acid (0.40 g of oxalic acid/75 g of H₂O) was added within 30 minutes while stirring the mixture at room temperature. Then, the flask was immersed in an oil bath at 30° C. and stirred for 30 minutes, and then the temperature of the oil bath was raised to 120° C. within 30 minutes. When the internal temperature of the solution reached 105° C., the mixture was continuously heated and stirred to perform polycondensation for 6 hours, thereby obtaining a polysiloxane polymer (B-5). The types of raw materials and the usage amount of each thereof of preparation embodiment B-5 are as shown in Table 3.

### Preparation Embodiment B-6

0.10 mol of MTMS, 0.40 mol of DMDMS, 0.45 mol of PTMS, 0.03 mol of GF-20, 0.02 mol of TMSOX, and 200 g of PGEE were added to a 500 mL 3-necked flask, and an aqueous solution of oxalic acid (0.45 g of oxalic acid/75 g of H₂O) was added within 30 minutes while stirring the mixture at room temperature. Then, the flask was immersed in an oil bath at 30° C. and stirred for 30 minutes, and then the temperature of the oil bath was raised to 120° C. within 30 minutes. When the internal temperature of the solution reached 110° C., the mixture was continuously heated and stifled to perform polycondensation for 6 hours, thereby obtaining a polysiloxane polymer (B-6). The types of raw materials and the usage amount of each thereof of preparation embodiment B-6 are as shown in Table 3.

The labels in Table 1 and Table 2 are described below:

| Label | Represented compound |
|---|---|
| a-2-1 | 3,3′,4,4′-biphenyltetracarboxylic dianhydride |
| a-2-2 | 3,3′,4,4′-benzophenone tetracarboxylic dianhydride |
| a-2-3 | 3,3′,4,4′-oxydiphenyltetracarboxylic dianhydride |
| a-3-1 | trimethoxysilylpropyl succinic anhydride |
| a-3-2 | triethoxysilylpropyl succinic anhydride |
| a-3-3 | methyldimethoxysilylpropyl succinic anhydride |
| a-3-4 | methyldiethoxysilylpropyl succinic anhydride |
| a-4-1 | butanedioic anhydride |
| a-4-2 | phthalic anhydride |
| PGMEA | propylene glycol monomethyl ether acetate |
| EEP | ethyl 3-ethoxypropionate |

The labels in Table 3 are described below:

| | | Molecular |
|---|---|---|
| Label | Represented compound | weight (Mw) |
| MTMS | methyltrimethoxysilane | 136 |
| DMDMS | dimethyl dimethoxy silane | 120 |
| PTMS | phenyltrimethoxysilane | 198 |
| PTES | phenyltriethoxysilane | 240 |
| GF-20 | 3-(triethoxysilyl) propyl succinic anhydride | 304 |
| TMSG | 3-(trimethoxysilyl) propyl glutaric anhydride | 276 |
| TMSOX | 3-ethyl-3-[(3-(trimethoxysilyl)propoxy)methyl] | 278 |
| | oxetane | |
| TESOX | 3-ethyl-3-[(3-(triethoxysilyl)propoxy)methyl] | 320 |
| | oxetane | |
| DMS-S27 | silanol terminal polysiloxane (manufactured by | 18000 |
| | Gelest, Inc.) | |
| PGEE | propylene glycol monoethyl ether | 104 |
| DAA | diacetone alcohol | 116 |

TABLE 1

| | | Component for polymerization | | | | | | | | | | | | | | |
|---|---|---|---|---|---|---|---|---|---|---|---|---|---|---|---|---|
| | | component | | | | | | component | | | component | | | | component | |
| | | (a-1) (mole) | | | | | | (a-2) (mole) | | | (a-3) (mole) | | | | (a-4) (mole) | |
| Component | | a-1-1 | a-1-2 | a-1-3 | a-1-4 | a-1-5 | a-1-6 | a-2-1 | a-2-2 | a-2-3 | a-3-1 | a-3-2 | a-3-3 | a-3-4 | a-4-1 | a-4-2 |
| Synthesis | A-1-1 | 1.0 | | | | | | 0.2 | | | 1.6 | | | | | |
| embodiment 1 | | | | | | | | | | | | | | | | |
| Synthesis | A-1-2 | | 1.0 | | | | | | 0.3 | | | 1.4 | | | | |
| embodiment 2 | | | | | | | | | | | | | | | | |
| Synthesis | A-1-3 | | | 1.0 | | | | | | 0.4 | | | 1.2 | | | |
| embodiment 3 | | | | | | | | | | | | | | | | |
| Synthesis | A-1-4 | 1.0 | | | | | | 0.5 | | | | | 0.5 | 0.5 | | |
| embodiment 4 | | | | | | | | | | | | | | | | |
| Synthesis | A-1-5 | | 1.0 | | | | | | 0.6 | | | 0.5 | | | 0.3 | |
| embodiment 5 | | | | | | | | | | | | | | | | |
| Synthesis | A-1-6 | | 0.5 | 0.5 | | | | | | 0.7 | | | 0.3 | | | 0.3 |
| embodiment 6 | | | | | | | | | | | | | | | | |
| Synthesis | A-1-7 | | | | 1.0 | | | 0.4 | 0.4 | | 0.3 | | | 0.1 | | |
| embodiment 7 | | | | | | | | | | | | | | | | |
| Synthesis | A-1-8 | | | | | 1.0 | | | 1.0 | | | 0.02 | | | | |
| embodiment 8 | | | | | | | | | | | | | | | | |
| Synthesis | A-1-9 | | | | | | 1.0 | | | 0.15 | | | 1.5 | | | |
| embodiment 9 | | | | | | | | | | | | | | | | |
| Synthesis | A-1-10 | 1.0 | | | | | | 0.5 | | | | | | 0.01 | | |
| embodiment 10 | | | | | | | | | | | | | | | | |

| | | | | Polymer- | | | | | | | | | |
|---|---|---|---|---|---|---|---|---|---|---|---|---|---|
| | | | | ization | | | | | | | | | |
| | | | Catalyst (g) | inhi- | | | | | Reac- | | | | |
| | | | benzyl- | bitor (g) | | | | | tion | Reac- | | Acid | |
| | | Monomer | triethyl- | 2,6-di- | | | | | temper- | tion | | value | |
| | | input | ammonium | t-butyl- | Solvent (g) | | (a-2)/ | (a-3)/ | ature | time | | (mgKOH/ | |
| Component | | method | chloride | p-cresol | PGMEA | EEP | (a-1) | (a-1) | (° C.) | (hours) | | g) | Mn |
| Synthesis | A-1-1 | simultaneously | 1.9 | 0.6 | 900 | | 0.2 | 1.6 | 110 | 2 | | 100 | 1566 |
| embodiment 1 | | addition | | | | | | | | | | | |
| Synthesis | A-1-2 | successively | 2.0 | 0.7 | 900 | | 0.3 | 1.4 | 90 | 2 | 4 | 90 | 1981 |
| embodiment 2 | | addition | | | | | | | | | | | |
| Synthesis | A-1-3 | simultaneously | 2.9 | 1.0 | 1000 | 100 | 0.4 | 1.2 | 115 | 1.5 | | 80 | 2412 |
| embodiment 3 | | addition | | | | | | | | | | | |
| Synthesis | A-1-4 | successively | 1.9 | 0.6 | 800 | | 0.5 | 1 | 95 | 1.5 | 4 | 110 | 2885 |
| embodiment 4 | | addition | | | | | | | | | | | |
| Synthesis | A-1-5 | simultaneously | 2.0 | 0.7 | | 800 | 0.6 | 0.5 | 110 | 2 | | 110 | 3050 |
| embodiment 5 | | addition | | | | | | | | | | | |
| Synthesis | A-1-6 | successively | 2.4 | 0.8 | 900 | | 0.7 | 0.3 | 90 | 2 | 3.5 | 90 | 3527 |
| embodiment 6 | | addition | | | | | | | | | | | |
| Synthesis | A-1-7 | simultaneously | 1.1 | 0.4 | 600 | | 0.8 | 0.4 | 115 | 1.5 | | 150 | 3964 |
| embodiment 7 | | addition | | | | | | | | | | | |
| Synthesis | A-1-8 | successively | 1.3 | 0.4 | 600 | | 1.0 | 0.02 | 95 | 2 | 3.5 | 140 | 4582 |
| embodiment 8 | | addition | | | | | | | | | | | |
| Synthesis | A-1-9 | simultaneously | 1.1 | 0.4 | 600 | | 0.15 | 1.5 | 110 | 2 | | 130 | 1395 |
| embodiment 9 | | addition | | | | | | | | | | | |
| Synthesis | A-1-10 | successively | 1.9 | 0.6 | 600 | | 0.5 | 0.01 | 90 | 2 | 4 | 70 | 3005 |
| embodiment 10 | | addition | | | | | | | | | | | |

TABLE 2

| | | Component for polymerization | | | | | | | | | | | | | | |
|---|---|---|---|---|---|---|---|---|---|---|---|---|---|---|---|---|
| | | component | | | | | | component | | | component | | | | component | |
| | | (a-1) (mole) | | | | | | (a-2) (mole) | | | (a-3) (mole) | | | | (a-4) (mole) | |
| Component | | a-1-1 | a-1-2 | a-1-3 | a-1-4 | a-1-5 | a-1-6 | a-2-1 | a-2-2 | a-2-3 | a-3-1 | a-3-2 | a-3-3 | a-3-4 | a-4-1 | a-4-2 |
| Comparative | A-2-1 | 1.0 | | | | | | 0.3 | | | | | | | 1.4 | |
| synthesis | | | | | | | | | | | | | | | | |
| embodiment 1 | | | | | | | | | | | | | | | | |
| Comparative | A-2-2 | | 1.0 | | | | | | 0.4 | | | | | | | 1.2 |
| synthesis | | | | | | | | | | | | | | | | |
| embodiment 2 | | | | | | | | | | | | | | | | |
| Comparative | A-2-3 | | | 1.0 | | | | | | 0.5 | | | | | 1.0 | |
| synthesis | | | | | | | | | | | | | | | | |
| embodiment 3 | | | | | | | | | | | | | | | | |

| | | | | Polymer- | | | | | | | | | |
|---|---|---|---|---|---|---|---|---|---|---|---|---|---|
| | | | | zation | | | | | | | | | |
| | | | Catalyst (g) | inhi- | | | | | Reac- | | | | |
| | | | benzyl- | bitor (g) | | | | | tion | Reac- | | Acid | |
| | | Monomer | triethyl- | 2,6-di- | | | | | temper- | tion | | value | |
| | | input | ammonium | t-butyl- | Solvent (g) | | (a-2)/ | (a-3)/ | ature | time | | (mgKOH/ | |
| Component | | method | chloride | p-cresol | PGMEA | EEP | (a-1) | (a-1) | (° C.) | (hours) | | g) | Mn |
| Comparative | A-2-1 | simultaneously | 1.9 | 0.6 | 700 | | 0.3 | — | 110 | 2 | | 130 | 1888 |
| synthesis | | addition | | | | | | | | | | | |
| embodiment 1 | | | | | | | | | | | | | |
| Comparative | A-2-2 | successively | 2.0 | 0.7 | 800 | | 0.4 | — | 90 | 2 | 4 | 120 | 2340 |
| synthesis | | addition | | | | | | | | | | | |
| embodiment 2 | | | | | | | | | | | | | |

| | | | | | | | | | | | |
|---|---|---|---|---|---|---|---|---|---|---|---|
| Comparative | A-2-3 | simultaneously | 2.9 | 1.0 | 900 | 0.5 | — | 115 | 2 | 90 | 3210 |
| synthesis | | addition | | | | | | | | | |
| embodiment 3 | | | | | | | | | | | |

TABLE 3

| | | | | | | | | | | | | | | Reac- | |
|---|---|---|---|---|---|---|---|---|---|---|---|---|---|---|---|
| Prepa- | Composition | | | | | | | | | | | | | tion | Polycon- |
| ration | silane monomer/polysiloxane (mol) | | | | | | | | | | | Catalyst (g) | | temper- | densation |
| embodi- | | | | | GF- | | | | DMS- | Solvent (g) | | | oxalic | ature | time |
| ment | MTMS | DMDMS | PTMS | PTES | 20 | TMSG | TMSOX | TESOX | S27 | PGEE | DAA | water | acid | (° C.) | (hours) |
| B-1 | 0.3 | | 0.65 | | 0.05 | | | | | 200 | | 75 | 0.4 | 105 | 6 |
| B-2 | | 0.4 | 0.4 | 0.2 | | | | | | 100 | 100 | 75 | 0.4 | 110 | 5 |
| B-3 | | 0.6 | 0.35 | | | 0.05 | | | | 200 | | 75 | 0.35 | 105 | 6 |
| B-4 | 0.65 | | | 0.25 | | | 0.09 | | 0.01 | 200 | | 75 | 0.45 | 110 | 6 |
| B-5 | | 0.3 | 0.62 | | | | | 0.08 | | 200 | | 75 | 0.4 | 105 | 6 |
| B-6 | 0.1 | 0.4 | 0.45 | | 0.03 | | 0.02 | | | 200 | | 75 | 0.45 | 110 | 6 |

### Preparation of Photosensitive Resin Composition

### Embodiment 1

100 parts by weight of the alkali-soluble resin (A-1-1), 10 parts by weight of the polysiloxane polymer (B−1), 40 parts by weight of TO-1382 (manufactured by Toa Gosei Co., Ltd., Japan, hereinafter referred to as C-1), 5 parts by weight of 2-methyl-1-(4-methylthio phenyl)-2-morpholino-1-propanone (hereinafter referred to as D-1), 10 parts by weight of 2,2′-bis(2,4-dichlorophenyl)-4,4′,5,5′-tetraphenyl-biimidazole (hereinafter referred to as D-2), 5 parts by weight of 4,4′-bis(diethylamino)benzophenone (hereinafter referred to as D-3), 20 parts by weight of C. I. pigment red 254/C. I. pigment yellow 139=80/20 (hereinafter referred to as F-1), and 500 parts by weight of propylene glycol mono-methyl ether acetate (hereinafter referred to as E-1) were mixed into a homogeneous solution state using a shaking type stirrer to obtain the photosensitive resin composition of the invention. The obtained photosensitive resin composition was tested by each of the following evaluation methods to obtain the results shown in Table 4.

### Evaluation Methods

### High Precision Pattern Linearity

The photosensitive resin composition was coated on a 100 mm×100 mm glass substrate by spin coating, and first dried under reduced pressure at a pressure of 100 mmHg and a time of 30 seconds, and then pre-baked at a temperature of 80° C. and a time of 3 minutes to form a pre-baked coating film with a film thickness of 2.5 μm. Next, the pre-baked coating film was irradiated by an ultraviolet light with 300 mJ/cm² of light intensity (exposure machine Canon PLA-501F) via a photomask with a stripe pattern having 25 gm in width (50 μm in pitch) so as to exposure the pre-baked coating film. Then, the pre-baked coating film was immersed in a developing solution at 23° C. for 2 minutes, washed with pure water, and post-baked at 200° C. for 80 minutes to form a photosensitive resin layer having a stripe pattern and a film thickness of 2.0 μm on the glass substrate.

The stripe pattern formed by aforementioned method was observed and evaluated using an optical microscope. The evaluation standards are as follows:

⊚: good linearity;

◯: linearity is partially poor;

X: poor linearity.

### <Size of Foreign Matter>

Foreign matter in the photosensitive resin layer having a film thickness of 2.0 μm was observed using an optical microscope. In particular, a smaller size of the foreign matter is preferred. The evaluation standards are as follows:

⊚: size of foreign matter <2 μm;

◯: 2 μm≦size of foreign matter<4 μm;

Δ: 4 μm≦size of foreign matter<6 μm;

X: 6 μm≦size of foreign matter.

### Embodiments 2 to 10 and Comparative Embodiments 1 to 5

In addition to the conditions indicated in Table 4 and Table 5, the photosensitive resin compositions were prepared using the same method as embodiment 1 and evaluated. The evaluation results are respectively recorded in Table 4 and Table 5.

The labels in Table 4 and Table 5 are described below:

| Label | Represented compound |
|---|---|
| C-1 | TO-1382 (manufactured by Toagosei Co, Ltd., Japan) |
| C-2 | KAYARAD DPCA-20 (manufacture by Nippon Kayaku Co., |
| | Ltd., Japan) |
| C-3 | dipentaerythritol hexaacrylate |
| D-1 | 2-methyl-1-(4-methylthio |
| | phenyl)-2-morpholino-1-propanone |
| D-2 | 2,2′-bis(2,4-dichlorophenyl)-4,4′,5,5′-tetraphenylbiimidazole |
| D-3 | 4,4′-bis(diethylamino)benzophenone |
| D-4 | 1-(4-phenyl-thio-phenyl)-octane-1,2-dion |
| | 2-oxime-O-benzoate |
| E-1 | propylene glycol monomethyl ether acetate |
| E-2 | ethyl 3-ethoxypropionate |
| F-1 | C.I. pigment red 254/C.I. pigment yellow 139 = 80/20 |
| F-2 | C.I. pigment green 36/C.I. pigment yellow 150 = 60/40 |
| F-3 | C.I. pigment blue 15:6 |
| F-4 | C.I. pigment black 7 |
| G-1 | 2,2-thiobis(4-methyl-6-t-butylphenol) |
| G-2 | 2-(3-t-butyl-5-methyl-2-hydroxyphenyl)-5-chlorophenylazide |

TABLE 4

| | | | Embodiment | | | | | | | | | |
|---|---|---|---|---|---|---|---|---|---|---|---|---|
| Component | | | 1 | 2 | 3 | 4 | 5 | 6 | 7 | 8 | 9 | 10 |
| alkai- | A-1 | A-1-1 | 100 | | | | | | | | | |
| soluble | | A-1-2 | | 100 | | | | | | | | |
| resin (A) | | A-1-3 | | | 100 | | | | | | | |
| (parts by | | A-1-4 | | | | 100 | 50 | | | | | |
| weight) | | A-1-5 | | | | | 50 | | | | | |
| | | A-1-6 | | | | | | 70 | | | | |
| | | A-1-7 | | | | | | | 50 | | | |
| | | A-1-8 | | | | | | | | 10 | | |
| | | A-1-9 | | | | | | | | | 100 | |
| | | A-1-10 | | | | | | | | | | 100 |
| | A-2 | A-2-1 | | | | | | 30 | | | | |
| | | A-2-2 | | | | | | | 50 | | | |
| | | A-2-3 | | | | | | | | 90 | | |

| | | | | | | | | | | | |
|---|---|---|---|---|---|---|---|---|---|---|---|
| | (A-1)/(A-2) | 100/0 | 100/0 | 100/0 | 100/0 | 100/0 | 70/30 | 50/50 | 10/90 | 100/0 | 100/0 |
| polysiloxane | B-1 | 10 | | | | | | | | 90 | |
| polymer (B) | B-2 | | 20 | | | | 60 | | | | 100 |
| (parts by | B-3 | | | 30 | | | | 70 | | | |
| weight) | B-4 | | | | 60 | | | 10 | | 10 | |
| | B-5 | | | | | 50 | | | | | |
| | B-6 | | | | | | | | 80 | | |
| compound (C) | C-1 | 40 | | | 200 | | | 300 | | | 200 |
| containing an | C-2 | | 80 | | 100 | 240 | | 100 | 400 | | |
| ethylenically | C-3 | | | 160 | | | 300 | | | 300 | 200 |
| unsaturated | | | | | | | | | | | |
| group (parts | | | | | | | | | | | |
| by weight) | | | | | | | | | | | |
| photoinitiator | D-1 | 5 | 10 | | 20 | 20 | | 30 | 20 | 50 | 50 |
| (D) (parts by | D-2 | 10 | 20 | 30 | 30 | 30 | 5 | 30 | | 50 | |
| weight) | D-3 | 5 | | | | | 25 | | 30 | | 30 |
| | D-4 | | | 20 | 30 | | 50 | | 10 | | 20 |
| organic | E-1 | 500 | | 2500 | 4500 | 3000 | 4000 | | 4000 | 2000 | 4000 |
| solvent (E) | E-2 | | 2000 | | | | | 5000 | 1000 | 2000 | |
| (parts by | | | | | | | | | | | |
| weight) | | | | | | | | | | | |
| colorant (F) | F-1 | 20 | | | | 40 | | | | | |
| (parts by | F-2 | | 60 | | | | 80 | | | | |
| weight) | F-3 | | | 100 | | | | 120 | | | |
| | F-4 | | | | 150 | | | | 140 | | |
| Additive (G) | G-1 | | | | | | 1 | | | | 10 |
| | G-2 | | 5 | | | | | | | | |
| Evaluation | high precision | ⊚ | ⊚ | ⊚ | ⊚ | ⊚ | ⊚ | ⊚ | ⊚ | ◯ | ◯ |
| result | pattern linearity | | | | | | | | | | |
| | size of foreign | ⊚ | ◯ | ⊚ | ⊚ | ⊚ | ◯ | ⊚ | ⊚ | ⊚ | ◯ |
| | matter | | | | | | | | | | |

TABLE 5

| | | | Comparative embodiment | | | | |
|---|---|---|---|---|---|---|---|
| Component | | | 1 | 2 | 3 | 4 | 5 |
| alkai- | A-1 | A-1-1 | | 100 | | | |
| soluble | | A-1-2 | | | 50 | | |
| resin (A) | | A-1-3 | | | | | |
| (parts by | | A-1-4 | | | | | |
| weight) | | A-1-5 | | | | | |
| | | A-1-6 | | | | | |
| | | A-1-7 | | | | | |
| | | A-1-8 | | | | | |
| | | A-1-9 | | | | | |
| | | A-1-10 | | | | | |
| | A-2 | A-2-1 | 100 | | | | |
| | | A-2-2 | | | 50 | | |
| | | A-2-3 | | | | | 100 |

| | | | | | | |
|---|---|---|---|---|---|---|
| | (A-1)/(A-2) | 0/100 | 100/0 | 50/50 | — | 0/100 |
| polysiloxane | B-1 | 50 | | | | |
| polymer (B) | B-2 | | | | | |
| (parts by | B-3 | | | | 100 | |
| weight) | B-4 | | | | | |
| | B-5 | | | | | |
| | B-6 | | | | | |
| compound (C) | C-1 | 200 | | | 200 | |
| containing an | C-2 | | 250 | | 100 | |
| ethylenically | C-3 | | | 300 | | 300 |
| unsaturated | | | | | | |
| group (parts | | | | | | |
| by weight) | | | | | | |
| photoinitiator | D-1 | 20 | | 50 | 20 | 50 |
| (D) (parts | D-2 | 30 | 5 | 50 | 30 | 50 |
| by weight) | D-3 | | 25 | | | |
| | D-4 | | 50 | | 30 | |
| organic | E-1 | 3000 | 4000 | | 4500 | 2000 |
| solvent (E) | E-2 | | | 5000 | | 2000 |
| (parts by | | | | | | |
| weight) | | | | | | |
| colorant (F) | F-1 | 60 | | | | |
| (parts by | F-2 | | 80 | | | |
| weight) | F-3 | | | 100 | | |
| | F-4 | | | | 120 | |
| Additive (G) | G-1 | | | | | |
| | G-2 | | | | | |
| Evaluation | high precision | X | X | X | X | X |
| result | pattern linearity | | | | | |
| | size of foreign | X | Δ | Δ | X | X |
| | matter | | | | | |

It can be known from Table 4 and Table 5 that, in comparison to the photosensitive resin compositions (comparative embodiments 1, 4, and 5) containing only the alkali-soluble resin (A-2), the photosensitive resin compositions (embodiments 1-10) containing the alkali-soluble resin (A-1) are all better in terms of high precision pattern linearity and size of foreign matter. Moreover, in comparison to the photosensitive resin compositions (comparative embodiments 2, 3, and 5) without the polysiloxane polymer (B), the photosensitive resin compositions (embodiments 1-10) containing the polysiloxane polymer (B) are all better in terms of high precision pattern linearity and size of foreign matter. Moreover, in comparison to the photosensitive resin compositions (comparative embodiments 2 and 3) without the polysiloxane polymer (B) for which the weight ratio of the alkali-soluble resin (A-1) and the alkali-soluble resin (A-2) is between 10/90 and 100/0, the photosensitive resin compositions (embodiments 1-10) containing the polysiloxane polymer (B) for which the weight ratio of the alkali-soluble resin (A-1) and the alkali-soluble resin (A-2) is between 10/90 and 100/0 are all better in terms of high precision pattern linearity and size of foreign matter.

Moreover, it can also be known from Table 4 and Table 5 that, in comparison to the photosensitive resin composition (embodiment 9) for which the molar ratio (a-2)/(a-1) of the component (a-1) and the component (a-2) in the alkali-soluble resin

(A-1) is 0.15, the photosensitive resin compositions (embodiments 1-8) for which the molar ratio (a-2)/(a-1) of the component (a-1) and the component (a-2) in the alkali-soluble resin (A-1) is within 0.2-1.0 are all better in terms of high precision pattern linearity.

Moreover, it can also be known from Table 4 and Table 5 that, in comparison to the photosensitive resin composition (embodiment 10) for which the molar ratio (a-3)/(a-1) of the component (a-1) and the component (a-3) in the alkali-soluble resin (A-1) is 0.01, the photosensitive resin compositions (embodiments 1-9) for which the molar ratio (a-3)/(a-1) of the component (a-1) and the component (a-3) in the alkali-soluble resin (A-1) is within 0.021.6 are all better in terms of high precision pattern linearity.

Based on the above, since the photosensitive resin composition of the invention contains a specific alkali-soluble resin and a specific polysiloxane polymer, the photosensitive resin composition has superior high precision pattern linearity and smaller size of foreign matter. As a result, the photosensitive resin composition is suitable for a color filter and a liquid crystal display apparatus.

Although the invention has been described with reference to the above embodiments, it will be apparent to one of the ordinary skill in the art that modifications to the described embodiments may be made without departing from the spirit of the invention. Accordingly, the scope of the invention is defined by the attached claims not by the above detailed descriptions.

What is claimed is:

1. A photosensitive resin composition, comprising:
an alkai-soluble resin (A);
a polysiloxane polymer (B);
a compound (C) containing an ethylenically unsaturated group;
a photoinitiator (D); and
an organic solvent (E),
wherein the alkali-soluble resin (A) comprises an alkali-soluble resin (A-1) represented by formula (1), 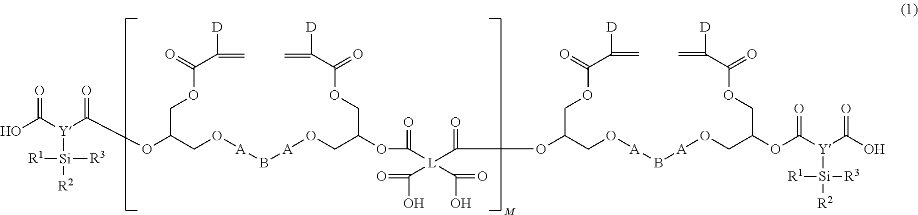
in formula (1), A represents a phenylene group, a hydrogen atom on the phenylene group can be substituted by a C1˜C5 alkyl group, a halogen atom, or a phenyl group;
B represents —CO—, —SO₂—, —C(CF₃)₂—, —Si(CH₃)₂—, —CH₂—, —C(CH₃)₂—, —O—, 9,9-fluorenylidene, or a single bond;
L represents a tetravalent carboxylic acid residue;
Y′ represents a C1˜C20 trivalent organic group;
R¹, R², and R³ are each independently a hydrogen atom, a halogen atom, or a monovalent organic group;
D represents a hydrogen atom or a methyl group; and
M is 1˜20.

2. The photosensitive resin composition of claim 1, wherein the alkai-soluble resin (A-1) is obtained by reacting at least a component (a-1), a component (a-2), and a component (a-3), the component (a-1) is a diol compound containing a polymeric unsaturated group, the component (a-2) is a tetracarboxylic acid or an acid dianhydride thereof, and the component (a-3) is a dicarboxylic acid anhydride represented by formula (2), 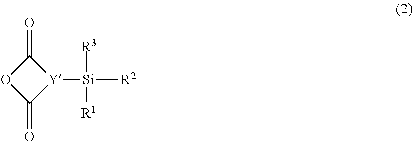
in formula (2), Y′ represents a C1˜C20 trivalent organic group;
R¹, R², and R³ are each independently a hydrogen atom, a halogen atom, or a monovalent organic group.

3. The photosensitive resin composition of claim 2, wherein a molar ratio (a-2)/(a-1) of the component (a-1) and the component (a-2) is 0.2˜1.0.

4. The photosensitive resin composition of claim 2, wherein a molar ratio (a-3)/(a-1) of the component (a-1) and the component (a-3) is 0.02˜1.6.

5. The photosensitive resin composition of claim 1, wherein the alkali-soluble resin (A) further comprises an alkali-soluble resin (A-2) other than the alkali-soluble resin (A-1), and the alkali-soluble resin (A-2) is obtained by performing a polymerization reaction on a mixture, wherein the mixture comprises an epoxy compound (a-i) having at least two epoxy groups and a compound (a-ii) having at least one carboxylic acid group and at least one ethylenically unsaturated group.

6. The photosensitive resin composition of claim 5, wherein the epoxy compound (a-i) having at least two epoxy groups has a structure represented by formula (3) or formula (4): 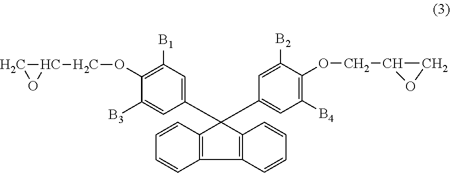
in formula (3), B₁, B₂, B₃, and B₄ are the same or respectively different, and B₁, B₂, B₃, and B₄ respectively represent a hydrogen atom, a halogen atom, a C1˜C5 alkyl group, a C1˜C5 alkoxy group, a C6˜C12 aryl group, or a C6˜C12 aralkyl group; 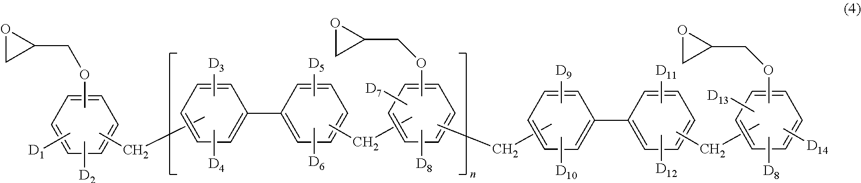
in formula (4), D₁ to D₁₄ are the same or respectively different, D₁ to D₁₄ respectively represent a hydrogen atom, a halogen atom, a C1˜C8 alkyl group, or a C6˜C15 aromatic group, and n represents an integer of 0˜10.

7. The photosensitive resin composition of claim 5, wherein a weight ratio of the alkali-soluble resin (A-1) and the alkali-soluble resin (A-2) is between 10/90 and 100/0.

8. The photosensitive resin composition of claim 1, wherein the polysiloxane polymer (B) is a copolymer obtained through a hydrolysis and a partial condensation of a silane monomer, wherein the silane monomer comprises a compound represented by formula (5):
Si(R¹²)ₜ(OR¹³)₄₋ₜ (5)
wherein t is an integer of 0˜3, and when t represents 2 or 3, a plurality of R¹²s are the same or each independently different;
R¹² represents a hydrogen atom, a C1˜C10 alkyl group, a C2˜C10 alkenyl group, a C6˜C15 aromatic group, an acid anhydride group substituted C1˜C10 alkyl group, an epoxy group substituted C1˜C10 alkyl group, or an epoxy group substituted alkoxy group;
R¹³ represents a hydrogen atom, a C1˜C6 alkyl group, a C1˜C6 acyl group, or a C6˜C15 aromatic group, and when 4-t represents 2 or 3, a plurality of R¹³s are the same or each independently different.

9. The photosensitive resin composition of claim 8, wherein at least one R¹² represents the acid anhydride group substituted C1˜C10 alkyl group, the epoxy group substituted C1˜C10 alkyl group, or the epoxy group substituted alkoxy group.

10. The photosensitive resin composition of claim 1, wherein based on a usage amount of 100 parts by weight of the alkai-soluble resin (A), a usage amount of the polysiloxane polymer (B) is between 10 and 100 parts by weight; a usage amount of the compound (C) containing an ethylenically unsaturated group is between 40 and 400 parts by weight; a usage amount of the photoinitiator (D) is between 10 and 100 parts by weight; and a usage amount of the organic solvent (E) is between 500 and 5000 parts by weight.

11. The photosensitive resin composition of claim 1, further comprising a colorant (F).

12. The photosensitive resin composition of claim 11, wherein based on a usage amount of 100 parts by weight of the alkali-soluble resin (A), a usage amount of the colorant (F) is 20 parts by weight to 150 parts by weight.

13. A method for manufacturing a color filter, comprising forming a pixel layer by using the photosensitive resin composition of claim 1.

14. A method for manufacturing a color filter, comprising forming a protective film by curing the photosensitive resin composition of claim 1.

15. A color filter, manufactured by the method of claim 13.

16. A color filter, manufactured by the method of claim 14.

17. A liquid crystal display apparatus, comprising the color filter of claim 15.

18. A liquid crystal display apparatus, comprising the color filter of claim 16.
